(19) United States
(12) Patent Application Publication
(10) Pub. No.: US 2018/0037688 A1
(43) Pub. Date: Feb. 8, 2018

(54) CURABLE COMPOSITION FOR IMPRINTS, CURED PRODUCT, PATTERN FORMING METHOD, LITHOGRAPHY METHOD, PATTERN AND LITHOGRAPHY MASK

(71) Applicant: FUJIFILM Corporation, Tokyo (JP)

(72) Inventors: Yuichiro GOTO, Haibara-gun (JP); Kazuhiro MARUMO, Haibara-gun (JP); Hirotaka KITAGAWA, Haibara-gun (JP); Tadashi OOMATSU, Haibara-gun (JP)

(73) Assignee: FUJIFILM Corporation, Tokyo (JP)

(21) Appl. No.: 15/703,115

(22) Filed: Sep. 13, 2017

Related U.S. Application Data
(63) Continuation of application No. PCT/JP2016/057904, filed on Mar. 14, 2016.

(30) Foreign Application Priority Data
Mar. 20, 2015 (JP) 2015-058287
Jun. 30, 2015 (JP) 2015-130762
Feb. 29, 2016 (JP) 2016-037872

(51) Int. Cl. C08F 222/14; B29C 59/02; G03F 7/00

(52) U.S. Cl. CPC C08F 222/14; G03F 7/0002; B29C 59/02; C08F 2800/20

(57) ABSTRACT

Provided are a curable composition for imprints which is capable of both improving releasability and suppressing occurrence of waviness during etching, as well as a cured product, a pattern forming method, a lithography method, a pattern, and a lithography mask, each of which uses the curable composition for imprints. The curable composition for imprints includes a monofunctional polymerizable compound, a polyfunctional polymerizable compound containing at least one of an alicyclic structure or an aromatic ring structure and having a viscosity at 25° C. of 150 mPa·s or less, and a photopolymerization initiator, in which the monofunctional polymerizable compound is contained in an amount of 5 to 30 mass % with respect to the total polymerizable compound in the curable composition for imprints, and the cured film of the curable composition for imprints has a modulus of elasticity of 3.5 GPa or less and a glass transition temperature of 90° C. or higher.

### CROSS-REFERENCE TO RELATED APPLICATIONS

This application is a Continuation of PCT International Application No. PCT/JP2016/057904 filed on Mar. 14, 2016, which claims priority under 35 U.S.C §119(a) to Japanese Patent Application No. 2015-058287 filed on Mar. 20, 2015, Japanese Patent Application No. 2015-130762 filed on Jun. 30, 2015, and Japanese Patent Application No. 2016-037872 filed on Feb. 29, 2016. Each of the above application(s) is hereby expressly incorporated by reference, in its entirety, into the present application.

### BACKGROUND OF THE INVENTION

### 1. Field of the Invention

The present invention relates to a curable composition for imprints. Further, the present invention relates to a cured product, a pattern forming method, a lithography method, a pattern, and a lithography mask, each of which uses the curable composition for imprints.

### 2. Description of the Related Art

The imprint method is a technique of transferring a fine pattern onto a material by pressing a mold (which is generally referred to as a “mold” or “stamper”), on which a pattern has been formed, against the material. Since use of the imprint method makes it possible to achieve easy and precise production of a fine pattern, this method has recently been expected to be applicable to various technical fields. In particular, attention has been paid to a nanoimprint technology for forming a fine pattern on a nano-order level.

As for the imprint method, there have been proposed methods known as a thermal imprint method and a photoimprint method, depending on the transfer method. In the thermal imprint method, a mold is pressed against a thermoplastic resin heated to a glass transition temperature (hereinafter, sometimes referred to as “Tg”) thereof or higher, then the resin is cooled, and the mold is released to thereby form a fine pattern. Although this method can select various materials, it also suffers from problems that a high pressure is required at the time of pressing and it is difficult to form a fine pattern due to thermal shrinkage or the like.

On the other hand, in the photoimprint method, a mold is released following photocuring of a curable composition for imprints in a state where the mold is pressed against the curable composition for imprints. Since this method is of imprinting for an uncured material, high pressure and high temperature heating is not necessary, which makes it possible to easily produce a fine pattern.

In the photoimprint method, a curable composition for imprints is applied onto a substrate (which is subjected to an adhesion treatment as necessary), and then a mold made of a light-transmissive material such as quartz is pressed against the substrate. The curable composition for imprints is cured by light irradiation in a state where the mold is pressed, and then the mold is released, whereby a cured product to which a desired pattern has been transferred is produced.

The method of applying the curable composition for imprints onto the substrate may be, for example, a spin coating method or an inkjet method. In particular, the inkjet method is an application method that has drawn attention in recent years from the viewpoint that the loss of the curable composition for imprints is small.

In addition, a method of carrying out microfabrication using a transferred imprint pattern as a mask is called nanoimprint lithography (NIL), which has been under development as a next-generation lithography technique. The curable composition for imprints used in NIL is required to have resist suitability such as a high etching selection ratio with respect to the object to be processed (high etching resistance) and no pattern deformation during etching processing, as well as nanoimprint suitability.

The method of improving releasability may be, for example, a method of blending a monofunctional polymerizable compound as described in JP2008-19292A, JP2010-159369A, JP2009-209245A, JP2010-206115A, and JP2014-76556A. In JP2008-19292A and JP2010-159369A, a (meth)acrylate monomer having an aromatic ring structure is used as the monofunctional polymerizable compound. In addition, in JP2009-209245A, JP2010-206115A, and JP2014-76556A, a (meth)acrylate monomer having a hydrophobic long-chain alkyl group or a (meth)acrylate monomer having a hydroxyl group is used as the monofunctional polymerizable compound. Further, in WO2008/155928A, a (meth)acrylate monomer having a fluoroalkyl group is used as the monofunctional polymerizable compound.

### SUMMARY OF THE INVENTION

The present inventors have examined the foregoing documents in detail, and have found that, in the case where imprint lithography was carried out using the curable composition for imprints described in the foregoing documents, defects and mold breakage occurred, or deformation (occurrence of waviness) of the pattern occurred at the time of etching, since the releasability of the curable composition for imprints from the mold was insufficient. The present invention has been made to solve the above-mentioned problems, and it is an object of the present invention to provide a curable composition for imprints which is capable of both improving releasability and suppressing occurrence of waviness during etching, as well as a cured product, a pattern forming method, a lithography method, a pattern, and a lithography mask, each of which uses the curable composition for imprints.

As a result of extensive studies under the above-described circumstances, the present inventors have found that excellent releasability can be achieved and the occurrence of waviness in the etching treatment (difference in line width roughness before and after etching, ΔLWR) can be suppressed by setting a modulus of elasticity of a cured film to a predetermined value or less and setting a Tg of the cured film to a predetermined value or more. The present invention has been completed based on these findings. Specifically, the foregoing objects have been achieved by the following means <1> and <21>, and preferably <2> to <23>.

<1> A curable composition for imprints, comprising a monofunctional polymerizable compound, a polyfunctional polymerizable compound containing at least one of an alicyclic structure or an aromatic ring structure and having a viscosity at 25° C. of 150 mPa·s or less, and a photopolymerization initiator, in which the monofunctional polymerizable compound is contained in an amount of more than 5 mass % and less than 30 mass % with respect to the total polymerizable compound in the curable composition for imprints, and the cured film of the curable composition for imprints has a modulus of elasticity of 3.5 GPa or less and a glass transition temperature of 90° C. or higher; where the modulus of elasticity is a value for a film having a thickness of 20 μm in terms of a cured film of a curable composition for imprints, as measured by a microhardness tester, the indenter at this time is of a triangular pyramid form with an angle of 115° between faces, and the measurement is carried out under the conditions of a test force of 10 mN, a load speed of 0.142 mN/sec, and a holding time of 5 seconds, with a temperature of 25° C. and a humidity of 50% at the time of measurement.

<2> The curable composition for imprints according to <1>, in which the monofunctional polymerizable compound has a linear or branched hydrocarbon chain having 4 or more carbon atoms.

<3> The curable composition for imprints according to <2>, in which the hydrocarbon chain is a linear or branched alkyl group.

<4> The curable composition for imprints according to <3>, in which the hydrocarbon chain is a linear alkyl group.

<5> The curable composition for imprints according to any one of <1> to <4>, in which a polymerizable group of the monofunctional polymerizable compound and a polymerizable group of the polyfunctional polymerizable compound containing at least one of an alicyclic structure or an aromatic ring structure are (meth)acryloyloxy groups.

<6> The curable composition for imprints according to any one of <1> to <5>, in which the polyfunctional polymerizable compound containing at least one of an alicyclic structure or an aromatic ring structure is a difunctional polymerizable compound.

<7> The curable composition for imprints according to any one of <1> to <6>, in which at least one of the polyfunctional polymerizable compounds containing at least one of an alicyclic structure or an aromatic ring structure is represented by General Formula (1),

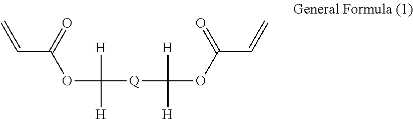

in General Formula (1), Q represents a divalent group having an alicyclic structure or an aromatic ring structure.

<8> The curable composition for imprints according to any one of <1> to <7>, in which the polyfunctional polymerizable compound containing at least one of an alicyclic structure or an aromatic ring structure has a viscosity at 25° C. of 50 mPa·s or less.

<9> The curable composition for imprints according to any one of <1> to <8>, in which the monofunctional polymerizable compound is contained in an amount of 10 to 25 mass % with respect to the total polymerizable compound in the curable composition for imprints.

<10> The curable composition for imprints according to any one of <1> to <9>, in which the polyfunctional polymerizable compound containing at least one of an alicyclic structure or an aromatic ring structure is contained in an amount of 45 to 90 mass % with respect to the total polymerizable compound in the curable composition for imprints.

<11> A curable composition for imprints, comprising a monofunctional polymerizable compound having a linear or branched alkyl group having 8 or more carbon atoms and having a viscosity at 25° C. of 10 mPa·s or less, a difunctional polymerizable compound containing at least one of an alicyclic structure or an aromatic ring structure and having a viscosity at 25° C. of 50 mPa·s or less, and a photopolymerization initiator, in which, with respect to the total polymerizable compound in the curable composition for imprints, the monofunctional polymerizable compound is contained in an amount of 10 to 25 mass % and the difunctional polymerizable compound is contained in an amount of 45 to 90 mass %.

<12> The curable composition for imprints according to any one of <1> to <11>, in which the Ohnishi parameter of the curable composition for imprints is 4.0 or less.

<13> The curable composition for imprints according to any one of <1> to <12>, in which the curable composition for imprints has a viscosity at 25° C. of 12 mPa·s or less.

<14> The curable composition for imprints according to any one of <1> to <13>, further comprising a mold release agent.

<15> The curable composition for imprints according to any one of <1> to <14>, further comprising a polyfunctional polymerizable compound containing no alicyclic structure and aromatic ring structure and having a viscosity at 25° C. of 10 mPa·s or less.

<16> The curable composition for imprints according to any one of <1> to <15>, in which the modulus of elasticity is 3.1 GPa or less.

<17> A cured product obtained by curing the curable composition for imprints according to any one of <1> to <16>.

<18> The cured product according to <17>, in which the cured product is located on a silicon substrate.

<19> A pattern forming method, comprising applying the curable composition for imprints according to any one of <1> to <16> onto a substrate or a mold, and subjecting the curable composition for imprints to light irradiation in a state of the curable composition for imprints being sandwiched between the mold and the substrate.

<20> The pattern forming method according to <19>, in which the size of the pattern is 30 nm or less.

<21> A lithography method in which etching is carried out using a pattern obtained by the method according to <19> or <20> as a mask.

<22> A pattern which is a cured product of the curable composition for imprints according to any one of <1> to <16> and has a pattern size of 30 nm or less.

<23> A lithography mask comprising at least one of the patterns according to <22>.

According to the present invention, it has become possible to provide a curable composition for imprints which is capable of both improving releasability and suppressing occurrence of waviness during etching, as well as a cured product, a pattern forming method, a lithography method, a pattern, and a lithography mask, each of which uses the curable composition for imprints.

### DESCRIPTION OF THE PREFERRED EMBODIMENTS

The contents of the present invention will be described in detail hereinunder.

As used herein, the numerical ranges shown with “to” means ranges including the numerical values indicated before and after “to” as the minimum and maximum values, respectively.

As used herein, the term “(meth)acrylate” refers to acrylate and methacrylate; “(meth)acrylic” refers to acrylic and methacrylic; and “(meth)acryloyl” refers to acryloyl and methacryloyl. The term “(meth)acryloyloxy” refers to acryloyloxy and methacryloyloxy.

As used herein, the term “imprint” is preferably meant to indicate pattern transfer in a size of 1 nm to 10 mm and more preferably meant to indicate pattern transfer in a size of about 10 nm to 100 μm (nanoimprint).

Regarding the expression of “group (atomic group)” as used herein, the expression with no indication of “substituted” or “unsubstituted” includes both “substituted group” and “unsubstituted group”. For example, “alkyl group” includes not only an alkyl group not having a substituent (unsubstituted alkyl group) but also an alkyl group having a substituent (substituted alkyl group).

As used herein, the term “light” includes not only those in the wavelength regions of ultraviolet, near-ultraviolet, far ultraviolet, visible light and infrared, and other electromagnetic waves, but also radiation rays. The radiation rays include microwaves, electron beams, extreme ultraviolet (EUV), and X-rays. Laser light such as 248 nm excimer laser, 193 nm excimer laser, and 172 nm excimer laser may also be used. These sorts of light may be monochromatic light (single wavelength light) which has passed through an optical filter, or light that includes a plurality of different wavelengths (complex light).

Unless otherwise specified, the weight-average molecular weight (Mw) in the present invention refers to that as measured by gel permeation chromatography (GPC).

The curable composition for imprints according to the present invention is a curable composition for imprints containing a monofunctional polymerizable compound, a polyfunctional polymerizable compound containing at least one of an alicyclic structure or an aromatic ring structure and having a viscosity at 25° C. of 150 mPa·s or less, and a photopolymerization initiator, in which the monofunctional polymerizable compound is contained in an amount of more than 5 mass % and less than 30 mass % with respect to the total polymerizable compound in the curable composition for imprints, and the cured film of the curable composition for imprints has a modulus of elasticity of 3.5 GPa or less and a glass transition temperature of 90° C. or higher.

Here, the modulus of elasticity is a value for a film having a thickness of 20 μm in terms of a cured film of a curable composition for imprints, as measured by a microhardness tester. As the indenter at this time, a triangular pyramid with an angle of 115° between faces is used. The value is determined under the measurement conditions of a test force of 10 mN, a load speed of 0.142 mN/sec, and a holding time of 5 seconds, with a temperature of 25° C. and a humidity of 50% at the time of measurement. More specifically, it refers to a value measured by the method shown in the Examples which will be described below. However, in the case where the measuring equipment cannot be obtained due to the waste version or the like, other models having equivalent performance can be used. Hereinafter, the same applies to other measurement methods.

In the present invention, it has been found that excellent releasability can be achieved and the occurrence of waviness (ΔLWR) in the etching treatment can be suppressed, by setting the modulus of elasticity of the cured film to a predetermined value or less and setting the Tg of the cured film to a predetermined value or more. In general, there is a trade-off relationship between lowering the modulus of elasticity and increasing the Tg, and it has been considered difficult to lower the modulus of elasticity while increasing the Tg. However, in the present invention, it has been found that, by including a monofunctional polymerizable compound in an amount of more than 5 mass % and less than 30 mass % in a curable composition for imprints containing a polyfunctional polymerizable compound having an alicyclic structure and/or an aromatic ring structure and having a relatively low viscosity, with respect to the total polymerizable compound in the curable composition for imprints, the cured film of the curable composition for imprints can satisfy both a low modulus of elasticity and a high Tg.

Such a curable composition for imprints in which the cured film satisfies both a low modulus of elasticity and a high Tg can be more easily obtained by using a monofunctional polymerizable compound having a linear or branched hydrocarbon chain having 4 or more carbon atoms.

Specifically, as one embodiment of the present invention, mention may be made of a curable composition for imprints containing a monofunctional polymerizable compound having a linear or branched alkyl group having 8 or more carbon atoms and having a viscosity at 25° C. of 10 mPa·s or less, a difunctional polymerizable compound having at least one of an alicyclic structure or an aromatic ring structure and a viscosity at 25° C. of 50 mPa·s or less, and a photopolymerization initiator, in which the curable composition for imprints contains 10 to 25 mass % of the monofunctional polymerizable compound and 45 to 90 mass % of the difunctional polymerizable compound, with respect to the total polymerizable compound in the curable composition for imprints.

Furthermore, the present inventors have made an attempt to improve the etching processability by adjusting the blending amount of the materials described in the above-mentioned JP2008-19292A, JP2010-159369A, JP2009-209245A, JP2010-206115A, JP2014-76556A, and WO2008/155928A, and it has been found that the filling properties of the curable composition for imprints were deteriorated (unfilled into the mold or increased filling time) due to an increase in the viscosity of the curable composition for imprints. This point proved to be a problem, in particular, in the case of forming a pattern of 30 nm or less. However, these problems can be solved in the present invention.

The Tg of the cured product of the curable composition for imprints according to the present invention is 90° C. or higher, more preferably 94° C. or higher, and still more preferably 100° C. or higher. The upper limit value of Tg is not particularly specified. The Tg of the cured product of the curable composition for imprints in the present invention refers to a value measured by the method specified in the Examples which will be described later. By setting the Tg of the cured product of the curable composition for imprints to be within such a range, the above effects of the present invention can be more effectively exhibited, and pattern disconnection after etching can be more effectively suppressed.

The modulus of elasticity in the curable composition for imprints according to the present invention is 3.5 GPa or less, preferably 3.1 GPa or less, more preferably 3.0 GPa or less, still more preferably 2.7 GPa or less, and even still more preferably 2.5 GPa or less. The lower limit value of the modulus of elasticity is preferably 1.0 GPa or more and more preferably 1.5 GPa or more. By setting the modulus of elasticity to be within such a range, it is possible to achieve both improvement of releasability and suppression of pattern collapse.

<Monofunctional Polymerizable Compound>

The type of the monofunctional polymerizable compound used in the present invention is not particularly specified as long as it does not depart from the spirit of the present invention. The monofunctional polymerizable compound used in the present invention preferably has a linear or branched hydrocarbon chain having 4 or more carbon atoms. In the present invention, the monofunctional polymerizable compound may be contained singly or two or more kinds thereof may be contained.

The monofunctional polymerizable compound used in the present invention preferably has an Ohnishi parameter of 4.0 or less, more preferably 3.9 or less, still more preferably 3.7 or less, and particularly preferably 3.5 or less. The lower limit value of the Ohnishi parameter is not particularly specified, but it may be set to, for example, 2.5 or more. In the case where the Ohnishi parameter is 4.0 or less, the etching rate can be lowered, the etching selection ratio with respect to the object to be processed is improved, and the etching processing margin is expanded.

Here, the Ohnishi parameter is a value calculated by the following equation.

Ohnishi parameter=(sum of the number of atoms of C, H, and O)/(number of C atoms−number of O atoms)

The molecular weight of the monofunctional polymerizable compound used in the present invention is preferably 100 or more, more preferably 200 or more, and still more preferably 220 or more. The upper limit value of the molecular weight is preferably 1,000 or less, more preferably 800 or less, still more preferably 300 or less, and particularly preferably 270 or less. By setting the lower limit value of the molecular weight to 200 or more, there may be a tendency to suppress the volatility. By setting the upper limit value of the molecular weight to 300 or less, there may be a tendency to reduce the viscosity.

The boiling point at 667 Pa of the monofunctional polymerizable compound used in the present invention is preferably 85° C. or higher, more preferably 110° C. or higher, and still more preferably 130° C. or higher. By setting the boiling point at 667 Pa to 85° C. or higher, the volatility can be suppressed. The upper limit value of the boiling point is not particularly specified, but the boiling point at 667 Pa may be set to, for example, 200° C. or lower.

The monofunctional polymerizable compound used in the present invention is preferably a liquid at 25° C.

In the present invention, the term “liquid at 25° C.” refers to a compound having fluidity at 25° C., for example, a compound having a viscosity at 25° C. of 1 to 100,000 mPa·s. The viscosity at 25° C. of the monofunctional polymerizable compound is, for example, more preferably 10 to 20,000 mPa·s and still more preferably 100 to 15,000 mPa·s.

By using a compound that is a liquid at 25° C., it is possible to adopt a configuration which is substantially free of a solvent. Here, the phrase “substantially free of a solvent” means that the content of the solvent with respect to the curable composition for imprints according to the present invention is, for example, 5 mass % or less, furthermore 3 mass % or less, and particularly 1 mass % or less.

The viscosity at 25° C. of the monofunctional polymerizable compound used in the present invention is preferably 100 mPa·s or less, more preferably 10 mPa·s or less, still more preferably 8 mPa·s or less, and particularly preferably 6 mPa·s or less. By setting the viscosity at 25° C. of the monofunctional polymerizable compound to 10 mPa·s or less, the viscosity of the curable composition for imprints can be reduced and the filling properties of the curable composition for imprints tend to be improved. The lower limit value of the viscosity is not particularly specified, but it may be set to, for example, 1 mPa·s or more.

The type of the polymerizable group contained in the monofunctional polymerizable compound used in the present invention is not particularly specified, and examples thereof include an ethylenically unsaturated bond-containing group and an epoxy group, among which an ethylenically unsaturated bond-containing group is preferable. Examples of the ethylenically unsaturated bond-containing group include a (meth)acryl group and a vinyl group, among which a (meth)acryl group is more preferable and an acryl group is still more preferable. Further, it is preferred that the (meth)acryl group is a (meth)acryloyloxy group.

The type of atom constituting the monofunctional polymerizable compound used in the present invention is not particularly specified, but it preferably consists only of an atom selected from a carbon atom, an oxygen atom, a hydrogen atom, and a halogen atom and more preferably consists only of an atom selected from a carbon atom, an oxygen atom, and a hydrogen atom.

The monofunctional polymerizable compound used in the present invention preferably has a linear or branched hydrocarbon chain having 4 or more carbon atoms. The hydrocarbon chain in the present invention represents an alkyl chain, an alkenyl chain, or an alkynyl chain, preferably an alkyl chain or an alkenyl chain, and more preferably an alkyl chain.

In the present invention, the alkyl chain represents an alkyl group and an alkylene group. Similarly, the alkenyl chain represents an alkenyl group and an alkenylene group, and the alkynyl chain represents an alkynyl group and an alkynylene group. Among them, a linear or branched alkyl group or alkenyl group is more preferable, a linear or branched alkyl group is still more preferable, and a linear alkyl group is even more preferable.

The above-mentioned linear or branched hydrocarbon chain (preferably an alkyl group) has 4 or more carbon atoms, preferably 6 or more carbon atoms, more preferably 8 or more carbon atoms, still more preferably 10 or more carbon atoms, and particularly preferably 12 or more carbon atoms. The upper limit value of the number of carbon atoms is not particularly specified, but it may be, for example, 25 or less.

The above-mentioned linear or branched hydrocarbon chain may contain an ether group (—O—), but it is preferable not to contain an ether group from the viewpoint of improving releasability.

By using such a monofunctional polymerizable compound having a hydrocarbon chain, the modulus of elasticity of the cured film is reduced and the releasability is improved with a relatively small addition amount thereof. Further, in the case of using a monofunctional polymerizable compound having a linear or branched alkyl group, the interfacial energy between the mold and the cured film can be lowered, and the releasability can be further improved.

Preferred examples of the hydrocarbon group contained in the monofunctional polymerizable compound used in the present invention include the following (1) to (3).

(1) a linear alkyl group having 8 or more carbon atoms

(2) a branched alkyl group having 10 or more carbon atoms

(3) an alicyclic or aromatic ring substituted with a linear or branched alkyl group having 5 or more carbon atoms

<<(1) Linear Alkyl Group Having 8 or More Carbon Atoms>>

The linear alkyl group having 8 or more carbon atoms more preferably has 10 or more carbon atoms, still more preferably 11 or more carbon atoms, and particularly preferably 12 or more carbon atoms. The number of carbon atoms in the linear alkyl group is preferably 20 or less, more preferably 18 or less, still more preferably 16 or less, and particularly preferably 14 or less.

<<(2) Branched Alkyl Group Having 10 or More Carbon Atoms>>

The branched alkyl group having 10 or more carbon atoms preferably has 10 to 20 carbon atoms, more preferably 10 to 16 carbon atoms, still more preferably 10 to 14 carbon atoms, and particularly preferably 10 to 12 carbon atoms.

<<(3) Alicyclic or Aromatic Ring Substituted with Linear or Branched Alkyl Group Having 5 or More Carbon Atoms>>

The linear or branched alkyl group having 5 or more carbon atoms is more preferably a linear alkyl group. The number of carbon atoms in the alkyl group is more preferably 6 or more, still more preferably 7 or more, and particularly preferably 8 or more. The number of carbon atoms in the alkyl group is preferably 14 or less, more preferably 12 or less, and still more preferably 10 or less.

The ring structure of the alicyclic or aromatic ring may be a monocyclic ring or a fused ring, but it is preferably a monocyclic ring. In the case of a fused ring, the number of rings is preferably two or three. The ring structure is preferably a 3- to 8-membered ring, more preferably a 5-membered ring or a 6-membered ring, and still more preferably a 6-membered ring. The ring structure is an alicyclic ring or an aromatic ring, but it is preferably an aromatic ring. Specific examples of the ring structure include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring. Among them, a cyclohexane ring, a tricyclodecane ring, an adamantane ring, or a benzene ring is more preferable, and a benzene ring is still more preferable.

The monofunctional polymerizable compound used in the present invention is preferably a compound in which a linear or branched hydrocarbon chain having 4 or more carbon atoms and a polymerizable group are bonded directly or through a linking group, and more preferably a compound in which a polymerizable group is directly bonded to any one of the groups (1) to (3). Examples of the linking group include —O—, —C(═O)—, —CH₂—, and a combination thereof. The monofunctional polymerizable compound used in the present invention is particularly preferably a linear alkyl (meth)acrylate in which (1) a linear alkyl group having 8 or more carbon atoms and a (meth)acryloyloxy group are directly bonded.

Hereinafter, as the monofunctional polymerizable compound preferably used in the present invention, the following first group and second group can be exemplified. However, it goes without saying that the present invention is not limited thereto. Further, the first group is more preferable than the second group.

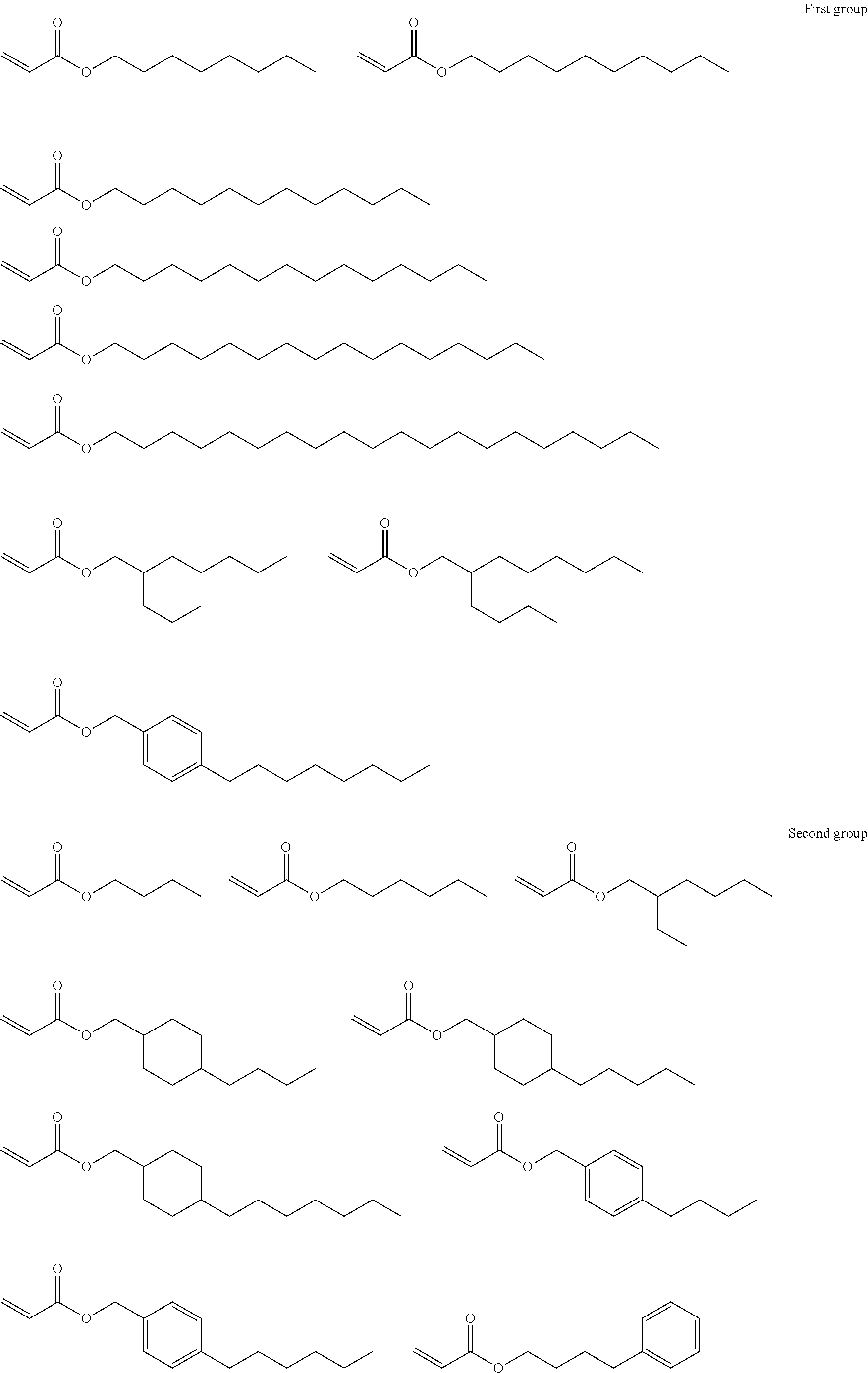

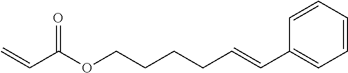 [SMILES: C=CC(=O)OCCCC/C=C/c1ccccc1]

The amount of the monofunctional polymerizable compound used in the present invention with respect to the total polymerizable compound in the curable composition for imprints is more than 5 mass % and less than 30 mass %. The lower limit value of the amount of the monofunctional polymerizable compound is preferably 6 mass % or more, more preferably 8 mass % or more, still more preferably 10 mass % or more, and particularly preferably 15 mass % or more. The upper limit value of the amount of the monofunctional polymerizable compound is more preferably 29 mass % or less, still more preferably 27 mass % or less, and particularly preferably 25 mass % or less. By setting the amount of the monofunctional polymerizable compound to 6 mass % or more with respect to the total polymerizable compound, the releasability can be improved, and defects and mold breakage at the time of mold releasing can be suppressed. Further, by setting the amount of the monofunctional polymerizable compound to 29 mass % or less, Tg of the cured film of the curable composition for imprints can be increased, and in terms of etching processability, in particular, waviness of the pattern during etching can be suppressed.

In the present invention, a monofunctional polymerizable compound other than the above-mentioned monofunctional polymerizable compound may be used as long as it does not depart from the spirit of the present invention. Mention may be made of monofunctional polymerizable compounds among the polymerizable compounds described in JP2014-170949A, the contents of which are incorporated by reference herein in its entirety.

In the present invention, it is preferred that 90 mass % or more of the total monofunctional polymerizable compounds contained in the curable composition for imprints is a monofunctional polymerizable compound having the foregoing groups (1) to (3), and it is more preferred that 95 mass % or more of the total monofunctional polymerizable compounds contained in the curable composition for imprints is a monofunctional polymerizable compound having the foregoing groups (1) to (3).

<Polyfunctional Polymerizable Compound>

The polyfunctional polymerizable compound used in the present invention is not particularly specified as long as it contains at least one of an alicyclic structure or an aromatic ring structure and has a viscosity at 25° C. of 150 mPa·s or less. In the following description, the polyfunctional polymerizable compound may be referred to as a ring structure-containing polyfunctional polymerizable compound. In the present invention, in terms of etching processing characteristics, particularly pattern disconnection after etching can be more effectively suppressed by using a ring structure-containing polyfunctional polymerizable compound. This is presumably because the etching selection ratio with respect to the object to be processed (for example, Si, Al, Cr, or an oxide thereof) in the case of etching processing is further improved.

In the present invention, the ring structure-containing polyfunctional polymerizable compound may be contained singly or two or more kinds thereof may be contained.

The ring structure-containing polyfunctional polymerizable compound used in the present invention has an Ohnishi parameter of preferably 4.2 or less, more preferably 4.0 or less, still more preferably 3.8 or less, even still more preferably 3.5 or less, and particularly preferably 3.3 or less. In the case where the Ohnishi parameter is 4.2 or less, the etching rate can be lowered, the etching selection ratio with respect to the object to be processed is improved, and the etching processing margin is expanded. The lower limit value of the Ohnishi parameter is not particularly specified, but it may be set to, for example, 2.5 or more.

The molecular weight of the ring structure-containing polyfunctional polymerizable compound used in the present invention is preferably 1,000 or less, more preferably 800 or less, still more preferably 500 or less, even more preferably 350 or less, and even still more preferably 250 or less. Setting the upper limit value of the molecular weight to 1,000 or less tends to reduce the viscosity.

The lower limit value of the molecular weight is not particularly specified, but it may be set to, for example, 200 or more.

The number of polymerizable groups contained in the ring structure-containing polyfunctional polymerizable compound used in the present invention is 2 or more, preferably 2 to 7, more preferably 2 to 4, still more preferably 2 or 3, and particularly preferably 2.

The type of the polymerizable group contained in the ring structure-containing polyfunctional polymerizable compound used in the present invention is not particularly specified, and examples thereof include an ethylenically unsaturated bond-containing group and an epoxy group, among which an ethylenically unsaturated bond-containing group is preferable. Examples of the ethylenically unsaturated bond-containing group include a (meth)acryl group and a vinyl group, among which a (meth)acryl group is more preferable and an acryl group is still more preferable. Also, it is preferred that the (meth)acryl group is a (meth)acryloyloxy group. Two or more kinds of polymerizable groups may be contained in one molecule or two or more polymerizable groups of the same kind may be contained.

The type of an atom constituting the ring structure-containing polyfunctional polymerizable compound used in the present invention is not particularly specified, but it preferably consists only of an atom selected from a carbon atom, an oxygen atom, a hydrogen atom, and a halogen atom, and more preferably consists only of an atom selected from a carbon atom, an oxygen atom, and a hydrogen atom.

The ring structure-containing polyfunctional polymerizable compound used in the present invention has a viscosity at 25° C. of 150 mPa·s or less, preferably 80 mPa·s or less, more preferably 50 mPa·s or less, still more preferably 30 mPa·s or less, and particularly preferably 10 mPa·s or less. The lower limit value of the viscosity is not particularly specified, but it may be set to, for example, 5 mPa·s or more.

The ring structure contained in the ring structure-containing polyfunctional polymerizable compound used in the present invention may be a monocyclic ring or a fused ring, but it is preferably a monocyclic ring. In the case of a fused ring, the number of rings is preferably two or three. The ring structure is preferably a 3- to 8-membered ring, more preferably a 5-membered ring or a 6-membered ring, and still more preferably a 6-membered ring. The ring structure may be an alicyclic ring or an aromatic ring, but it is preferably an aromatic ring. Specific examples of the ring structure include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring. Among them, a cyclohexane ring, a tricyclodecane ring, an adamantane ring, or a benzene ring is more preferable, and a benzene ring is still more preferable.

The number of ring structures in the ring structure-containing polyfunctional polymerizable compound used in the present invention may be one or two or more, but it is preferably one or two and more preferably one. In the case of a fused ring, it is considered as one ring.

The ring structure-containing polyfunctional polymerizable compound used in the present invention is preferably represented by (polymerizable group)-(single bond or divalent linking group)-(divalent group having ring structure)-(single bond or divalent linking group)-(polymerizable group). Here, the linking group is more preferably an alkylene group and still more preferably an alkylene group having 1 to 3 carbon atoms.

The ring structure-containing polyfunctional polymerizable compound used in the present invention is preferably represented by General Formula (1).

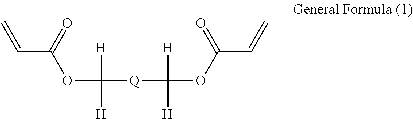

In General Formula (1), Q represents a divalent group having an alicyclic structure or an aromatic ring structure.

The alicyclic ring or aromatic ring (ring structure) in Q has the same meaning as described above and the preferred range thereof is also the same.

As the polyfunctional polymerizable compound preferably used in the present invention, the following first group and second group given below can be exemplified. However, it goes without saying that the present invention is not limited thereto. Further, the first group is more preferable.

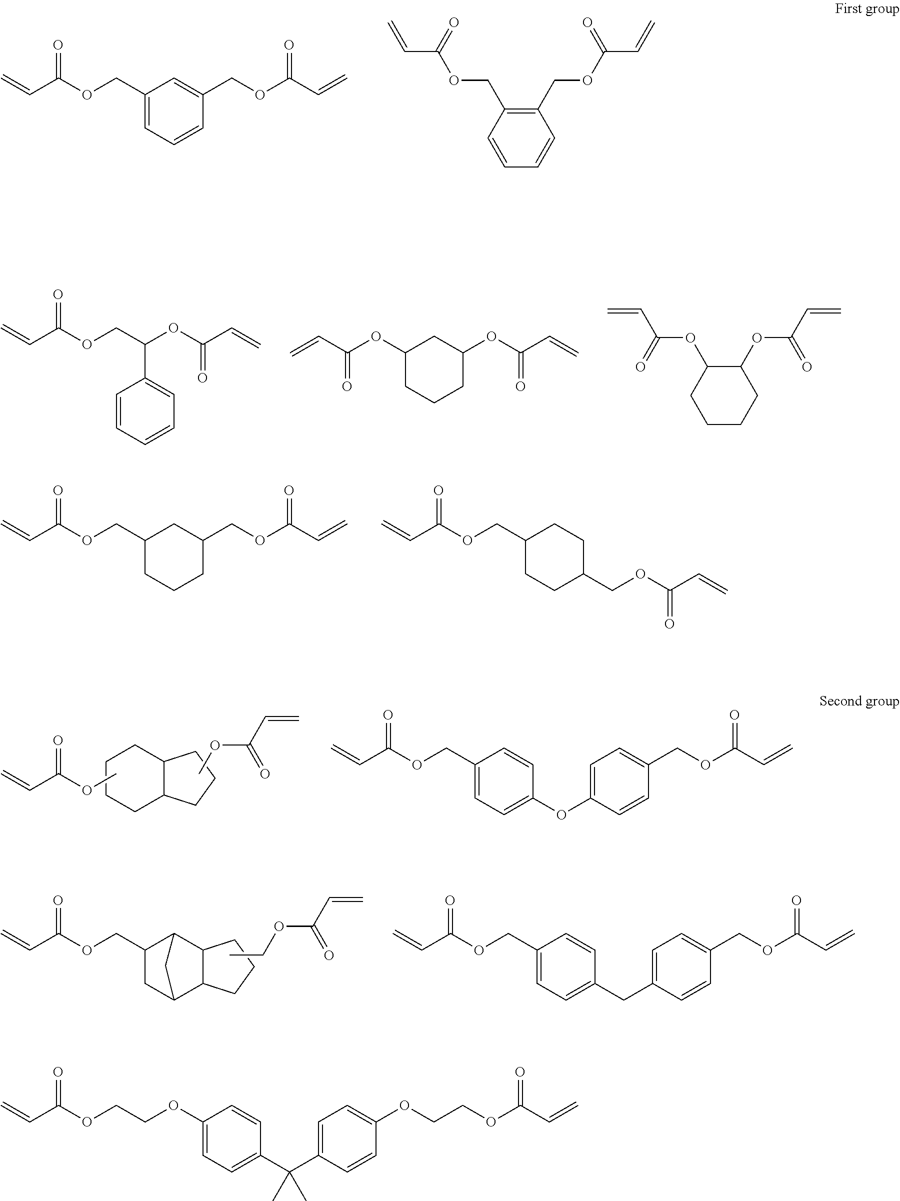

The ring structure-containing polyfunctional polymerizable compound is contained in an amount of preferably 30 mass % or more, more preferably 45 mass % or more, still more preferably 50 mass % or more, and even still more preferably 55 mass % or more, with respect to the total polymerizable compound in the curable composition for imprints. The amount of the ring structure-containing polyfunctional polymerizable compound may be 60 mass % or more or may be 70 mass % or more. Also, the upper limit value of the amount of the ring structure-containing polyfunctional polymerizable compound is preferably less than 95 mass % and more preferably 90 mass % or less, and may also be set to 85 mass % or less. By setting the lower limit value of the amount of the ring structure-containing polyfunctional polymerizable compound to 30 mass % or more, the etching selection ratio with respect to the object to be processed (for example, Si, Al, Cr, or an oxide thereof) in the case of etching processing is improved, and disconnection of the pattern or the like after etching processing can be suppressed.

<Other Polyfunctional Polymerizable Compound>

In the present invention, a polyfunctional polymerizable compound other than the foregoing ring structure-containing polyfunctional polymerizable compound may be contained. The other polyfunctional polymerizable compound may be contained alone or two or more kinds thereof may be contained.

The other polyfunctional polymerizable compound used in the present invention preferably has no ring structure.

The other polyfunctional polymerizable compound used in the present invention preferably has an Ohnishi parameter of 4.5 or less. The lower limit value of the Ohnishi parameter is not particularly specified, but it may be set to, for example, 3.0 or more.

The molecular weight of the other polyfunctional polymerizable compound used in the present invention is preferably 1,000 or less, more preferably 800 or less, still more preferably 500 or less, even more preferably 350 or less, and even still more preferably 230 or less. Setting the upper limit value of the molecular weight to 1,000 or less tends to reduce the viscosity.

The lower limit value of the molecular weight is not particularly specified, but it may be set to, for example, 170 or more.

The number of polymerizable groups contained in the other polyfunctional polymerizable compound used in the present invention is 2 or more, preferably 2 to 7, more preferably 2 to 4, still more preferably 2 or 3, and particularly preferably 2.

The type of the polymerizable group contained in the other polyfunctional polymerizable compound used in the present invention is not particularly specified, and examples thereof include an ethylenically unsaturated bond-containing group and an epoxy group, among which an ethylenically unsaturated bond-containing group is preferable. Examples of the ethylenically unsaturated bond-containing group include a (meth)acryl group and a vinyl group, among which a (meth)acryl group is more preferable and an acryl group is still more preferable. Also, it is preferred that the (meth)acryl group is a (meth)acryloyloxy group.

The type of an atom constituting the other polyfunctional polymerizable compound used in the present invention is not particularly specified, but it preferably consists only of an atom selected from a carbon atom, an oxygen atom, a hydrogen atom, and a halogen atom, and more preferably consists only of an atom selected from a carbon atom, an oxygen atom, and a hydrogen atom.

The other polyfunctional polymerizable compound used in the present invention has a viscosity at 25° C. of preferably 180 mPa·s or less, more preferably 10 mPa·s or less, still more preferably 7 mPa·s or less, and particularly preferably 5 mPa·s or less. The lower limit value of the viscosity is not particularly specified, but it may be set to, for example, 2 mPa·s or more.

It is particularly preferred that the other polyfunctional polymerizable compound used in the present invention does not have a ring structure (alicyclic structure or aromatic ring structure) and has a viscosity at 25° C. of 10 mPa·s or less.

Examples of the other polyfunctional polymerizable compound preferably used in the present invention include polyfunctional polymerizable compounds having no ring structure among the polymerizable compounds described in JP2014-170949A, the contents of which are incorporated by reference herein in its entirety. More specifically, for example, the following compounds may be exemplified.

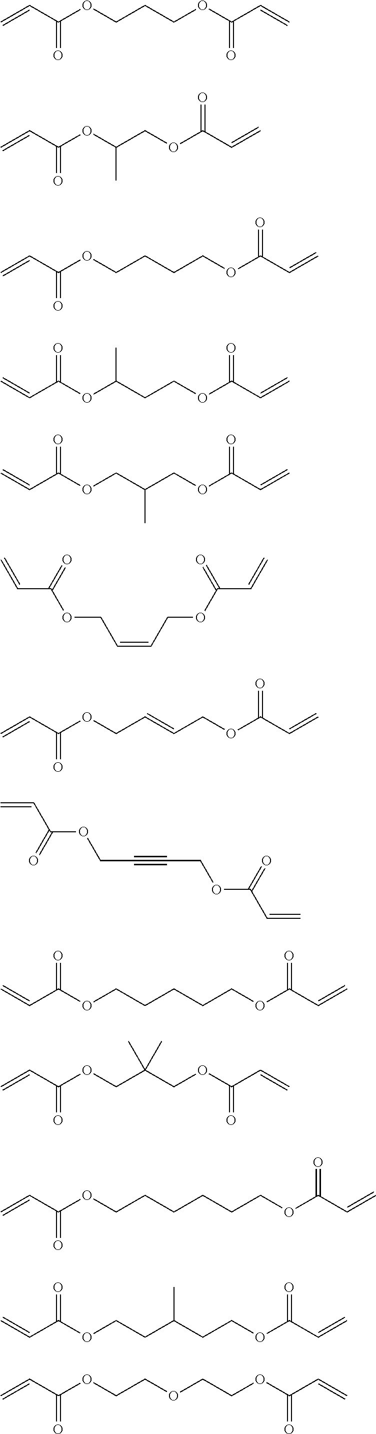

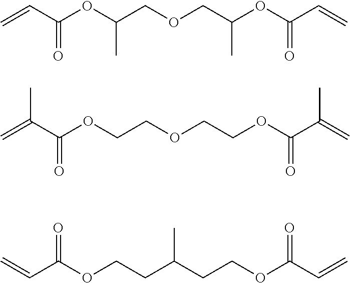

In the case where the other polyfunctional polymerizable compound is blended, the amount thereof is preferably 5 to 30 mass % with respect to the total polymerizable compound in the curable composition for imprints. Further, it is also possible to adopt a configuration which is substantially free of the other polyfunctional polymerizable compound. The phrase “substantially free of” refers to that the amount of the other polyfunctional polymerizable compound with respect to the total polymerizable compound in the curable composition for imprints is, for example, 3 mass % or less and furthermore 1 mass % or less.

<Photopolymerization Initiator>

As the photopolymerization initiator used in the present invention, any compound capable of generating active species that polymerize the above-mentioned polymerizable compound by light irradiation can be used. The photopolymerization initiator is preferably a radical photopolymerization initiator or a cationic photopolymerization initiator and more preferably a radical photopolymerization initiator.

As the radical photopolymerization initiator, for example, commercially available initiators may be used. As examples of these, for example, those described in paragraph “0091” of JP2008-105414A can be preferably adopted. Of these, an acetophenone-based compound, an acylphosphine oxide-based compound, and an oxime ester-based compound are preferred from the viewpoint of curing sensitivity and absorption characteristics. Examples of commercially available products of the radical photopolymerization initiator include IRGACURE (registered trademark) 1173, IRGACURE 184, IRGACURE 2959, IRGACURE 127, IRGACURE 907, IRGACURE 369, IRGACURE 379, LUCIRIN (registered trademark) TPO, IRGACURE 819, IRGACURE OXE-01, IRGACURE OXE-02, IRGACURE 651, and IRGACURE 754 (all manufactured by BASF Corporation).

In the present invention, an oxime compound having a fluorine atom may also be used as the photopolymerization initiator. Specific examples of the oxime compound having a fluorine atom include the compounds described in JP2010-262028A, the compounds 24 and 36 to 40 described in JP2014-500852A, and the compound (C-3) described in JP2013-164471A. The contents of the foregoing patent publications are incorporated by reference herein in their entirety.

Although one type of photopolymerization initiator may be used alone, it is also preferable to use two or more types of photopolymerization initiators in combination. It is more preferable to use two or more photopolymerization initiators in combination. Specifically, a combination of IRGACURE 1173 and IRGACURE 907, IRGACURE 1173 and LUCIRIN TPO, IRGACURE 1173 and IRGACURE 819, IRGACURE 1173 and IRGACURE OXE 01, IRGACURE 907 and LUCIRIN TPO, or IRGACURE 907 and IRGACURE 819 is exemplified. By adopting such a combination, the exposure margin can be expanded.

In the curable composition for imprints used in the present invention, a photopolymerization initiator is in an amount of preferably 0.01 to 10 mass %, more preferably 0.1 to 5 mass %, and still more preferably 0.5 to 3 mass %. The curable composition for imprints may contain only one photopolymerization initiator or two or more photopolymerization initiators. In the case of containing two or more photopolymerization initiators, the total amount thereof is preferably within the above-specified range.

<Sensitizer>

In addition to the photopolymerization initiator, a sensitizer may be added to the curable composition for imprints used in the present invention. In the case where the curable composition for imprints according to the present invention is hard to be cured under an oxygen atmosphere, the curability may be improved by adding a sensitizer.

Preferred examples of the sensitizer include compounds belonging to the following compounds and having an absorption wavelength in the region of 350 nm to 450 nm. Polynuclear aromatic compounds (for example, pyrene, perylene, triphenylene, anthracene, and phenanthrene), xanthenes (for example, fluorescein, eosin, erythrosine, rhodamine B, and rose bengal), xanthones (for example, xanthone, thioxanthone, dimethylthioxanthone, diethylthioxanthone, 2-isopropylthioxanthone, and 2-chlorothioxanthone), cyanines (for example, thiacarbocyanine and oxacarbocyanine), merocyanines (for example, merocyanine and carbomerocyanine), rhodacyanines, oxonols, thiazines (for example, thionine, methylene blue, and toluidine blue), acridines (for example, acridine orange, chloroflavin, acriflavine, and benzoflavin), acridones (for example, acridone and 10-butyl-2-chloroacridone), anthraquinones (for example, anthraquinone and 9,10-dibutoxyanthracene), squaryliums (for example, squarylium), styryls, base styryls, coumarins (for example, 7-diethylamino-4-methylcoumarin and ketocoumarin), carbazoles (for example, N-vinylcarbazole), camphorquinones, and phenothiazines.

Further, typical sensitizers that can be used in the present invention include those disclosed in J. V. Crivello, Adv. In Polymer Sci., 62, 1 (1984).

Preferred specific examples of the sensitizer include pyrene, perylene, acridine orange, thioxanthone, 2-chlorothioxanthone, benzoflavin, N-vinylcarbazole, 9,10-dibutoxyanthracene, anthraquinone, coumarin, ketocoumarin, phenanthrene, camphorquinone, and phenothiazines.

In the present invention, the compounds described in paragraphs “0043” to “0046” of JP4937806B and paragraph “0036” of JP2011-3916A can also preferably be used as the sensitizer.

In the case of being contained in the curable composition for imprints according to the present invention, the sensitizer is preferably added in a proportion of 30 to 200 parts by mass with respect to 100 parts by mass of the photopolymerization initiator.

The sensitizer may be contained in the curable composition for imprints according to the present invention singly or in combination of two or more thereof. In the case where two or more sensitizers are contained, the total amount thereof is preferably within the above-specified range.

<Mold Release Agent>

The mold release agent to be used in the present invention is not particularly specified as long as it does not depart from the spirit of the present invention, but it preferably refers to an additive having a function of segregating at the interface with the mold and promoting release from the mold. Specific examples thereof include a surfactant, and a non-polymerizable compound having at least one hydroxyl group at the terminal or having a polyalkylene glycol structure in which the hydroxyl group is etherified and substantially not containing fluorine atoms and silicon atoms (hereinafter, sometimes referred to as a “non-polymerizable compound having releasability”).

The mold release agent may be used alone or in combination of two or more thereof. In the case of containing a mold release agent, the total content thereof is preferably 0.1 to 20 mass %, more preferably 1 to 10 mass %, and still more preferably 2 to 5 mass %.

<<Surfactant>>

The surfactant is preferably a nonionic surfactant.

The nonionic surfactant is a compound having at least one hydrophobic moiety and at least one nonionic hydrophilic moiety. The hydrophobic moiety and the hydrophilic moiety may be respectively present at the terminal of a molecule or may be present within the molecule. The hydrophobic moiety is formed of a hydrophobic group selected from a hydrocarbon group, a fluorine-containing group, and a Si-containing group, and the number of carbon atoms in the hydrophobic moiety is preferably 1 to 25, more preferably 2 to 15, still more preferably 4 to 10, and even still more preferably 5 to 8. The nonionic hydrophilic moiety preferably has at least one group selected from the group consisting of an alcoholic hydroxyl group, a phenolic hydroxyl group, an ether group (preferably a polyoxyalkylene group or a cyclic ether group), an amido group, an imido group, a ureido group, a urethane group, a cyano group, a sulfonamido group, a lactone group, a lactam group, and a cyclocarbonate group. The nonionic surfactant may be any one nonionic surfactant of a hydrocarbon-based nonionic surfactant, a fluorine-based nonionic surfactant, a Si-based nonionic surfactant, and a fluorine.Si-based nonionic surfactant, but it is preferably a fluorine-based or Si-based nonionic surfactant and more preferably a fluorine-based nonionic surfactant. Here, the “fluorine.Si-based surfactant” refers to a surfactant satisfying requirements of both a fluorine-based surfactant and a Si-based surfactant.

Examples of commercially available fluorine-based nonionic surfactant include FLUORAD FC-4430 and FC-4431 (manufactured by Sumitomo 3M Limited), SURFLON S-241, S-242, and S-243 (manufactured by Asahi Glass Co., Ltd.), EFTOP EF-PN31M-03, EF-PN31M-04, EF-PN31M-05, EF-PN31M-06, and MF-100 (manufactured by Mitsubishi Materials Electronic Chemicals Co., Ltd.), POLYFOX PF-636, PF-6320, PF-656, and PF-6520 (manufactured by OMNOVA Solutions Inc.), FTERGENT 250, 251, 222F, 212M, and DFX-18 (manufactured by Neos Company Limited), UNIDYNE DS-401, DS-403, DS-406, DS-451, and DSN-403N (manufactured by Daikin Industries Ltd.), MEGAFACE F-430, F-444, F-477, F-553, F-556, F-557, F-559, F-562, F-565, F-567, F-569, and R-40 (manufactured by DIC Corporation), and CAPSTONE FS-3100 and ZONYL FSO-100 (manufactured by E.I. du Pont de Nemours and Company).

In the case where the curable composition for imprints according to the present invention contains a surfactant, the content of the surfactant is preferably 0.1 to 10 mass %, more preferably 0.2 to 5 mass %, and still more preferably 0.5 to 5 mass %, based on the total composition excluding the solvent. The curable composition for imprints may contain only one type of surfactant or two or more types thereof. In the case of containing two or more surfactants, the total amount thereof is preferably within the above-specified range.

Further, in the present invention, it is also possible to adopt an embodiment which is substantially free of a surfactant. The phrase “substantially free of a surfactant” means that the content of the surfactant is, for example, 0.01 mass % or less and preferably 0.005 mass % or less, based on the total composition excluding the solvent. It is still more preferable not to contain a surfactant.

<<Non-Polymerizable Compound Having Releasability>>

The curable composition for imprints may contain a non-polymerizable compound having at least one hydroxyl group at the terminal or having a polyalkylene glycol structure in which the hydroxyl group is etherified and substantially not containing fluorine atoms and silicon atoms. Here, the non-polymerizable compound refers to a compound having no polymerizable group. Further, the phrase “substantially not containing fluorine atoms and silicon atoms” means that the total content of fluorine atoms and silicon atoms is, for example, 1 mass % or less. It is preferred that the non-polymerizable compound has no fluorine atoms or silicon atoms at all. No incorporation of fluorine atoms and silicon atoms results in improved compatibility with the polymerizable compound, and satisfactory coating uniformity, pattern formability upon imprinting, and line edge roughness after dry etching, particularly in a curable composition for imprints which does not contain a solvent.

The polyalkylene structure contained in the non-polymerizable compound having releasability is preferably a polyalkylene glycol structure containing an alkylene group having 1 to 6 carbon atoms, more preferably a polyethylene glycol structure, a polypropylene glycol structure, a polybutylene glycol structure, or a mixed structure thereof, still more preferably a polyethylene glycol structure, a polypropylene glycol structure, or a mixed structure thereof, and particularly preferably a polypropylene glycol structure.

Further, the non-polymerizable compound having releasability may be constituted solely of a polyalkylene glycol structure substantially excluding terminal substituents. The term “substantially” as used herein means that the constituent elements other than the polyalkylene glycol structure are 5 mass % or less and preferably 1 mass % or less, with respect to the total compound. In particular, it is particularly preferable to contain a compound consisting substantially of only a polypropylene glycol structure as the non-polymerizable compound having releasability.

The polyalkylene glycol structure preferably has 3 to 100 alkylene glycol constitutional units, more preferably 4 to 50 alkylene glycol constitutional units, still more preferably 5 to 30 alkylene glycol constitutional units, and particularly preferably 6 to 20 alkylene glycol constitutional units.

It is preferred that the non-polymerizable compound having releasability has at least one hydroxyl group at the terminal or the hydroxyl group therein is etherified. In the case where at least one hydroxyl group is present at the terminal or in the case where the hydroxyl group is etherified, the remaining terminal may be a hydroxyl group and the hydrogen atom of the terminal hydroxyl group may be substituted. As the group in which the hydrogen atom of the terminal hydroxyl group may be substituted, an alkyl group (that is, a polyalkylene glycol alkyl ether) or an acyl group (that is, a polyalkylene glycol ester) is preferable. A compound having a plurality of (preferably 2 or 3) polyalkylene glycol chains through a linking group may also be preferably used.

Preferred specific examples of the non-polymerizable compound having releasability include polyethylene glycol, polypropylene glycol (for example, one manufactured by Wako Pure Chemical Industries, Ltd.), their mono or dimethyl ether, mono or dibutyl ether, mono or dioctyl ether, mono or dicetyl ether, monostearic acid ester, monooleic acid ester, polyoxyethylene glyceryl ether, polyoxypropylene glyceryl ether, and trimethyl ether thereof.

The weight-average molecular weight of the non-polymerizable compound having releasability is preferably 150 to 6,000, more preferably 200 to 3,000, still more preferably 250 to 2,000, and even still more preferably 300 to 1,200.

Examples of the non-polymerizable compound having releasability that can be used in the present invention also include a non-polymerizable compound containing an acetylene diol structure and having releasability. The commercially available product of such a non-polymerizable compound having releasability may be, for example, OLFINE E 1010.

In the case where the curable composition for imprints according to the present invention contains a non-polymerizable compound having releasability, the content of the non-polymerizable compound having releasability is preferably 0.1 mass % or more, more preferably 0.5 mass % or more, still more preferably 1.0 mass % or more, and particularly preferably 2 mass % or more, based on the total composition excluding the solvent. The content of the non-polymerizable compound having releasability is preferably 20 mass % or less, more preferably 10 mass % or less, and still more preferably 5 mass % or less.

The curable composition for imprints may contain only one type of non-polymerizable compound having releasability, or may contain two or more types thereof. In the case of containing two or more non-polymerizable compounds, the total amount thereof is preferably within the above-specified range.

<Antioxidant>

The curable composition for imprints according to the present invention may contain an antioxidant. Examples of the antioxidant include a phenol-based antioxidant, a phosphorus-based antioxidant, and a sulfur-based antioxidant.

Specific examples of the phenol-based antioxidant may include 2,6-di-t-butyl-4-methylphenol, n-octadecyl-3-(3′,5′-di-t-butyl-4′-hydroxyphenyl)propionate, tetrakis[methylene-3-(3,5-di-t-butyl-4-hydroxyphenyl)propionate]methane, tris(3,5-di-t-butyl-4-hydroxybenzyl)isocyanurate, 4,4′-butylidenebis-(3-methyl-6-t-butylphenol), triethylene glycol-bis[3-(3-t-butyl-4-hydroxy-5-methylphenyl)propionate], and 3,9-bis {2-[3-(3-t-butyl-4-hydroxy-5-methylphenyl)propionyloxy]-1,1-dimethylethyl}-2,4,8,10-tetraoxaspiro[5,5]undecane.

Examples of commercially available phenol-based antioxidants include IRGANOX 1010, IRGANOX 1035, IRGANOX 1076, IRGANOX 1135, IRGANOX 245, IRGANOX 259, IRGANOX 295, and IRGANOX 3114 (all manufactured by BASF Corporation), ADEKA STAB AO-20, ADEKA STAB AO-30, ADEKA STAB AO-40, ADEKA STAB AO-50, ADEKA STAB AO-60, ADEKA STAB AO-70, ADEKA STAB AO-80, ADEKA STAB AO-90, and ADEKA STAB AO-330 (all manufactured by ADEKA Corporation), SUMILIZER BHT, SUMILIZER BP-101, SUMILIZER GA-80, SUMILIZER MDP-S, SUMILIZER BBM-S, SUMILIZER GM, SUMILIZER GS (F), and SUMILIZER GP (all manufactured by Sumitomo Chemical Company), HOSTANOX O10, HOSTANOX O16, HOSTANOX O14, and HOSTANOX O3 (all manufactured by Clariant Japan K.K.), ANTAGE BHT, ANTAGE W-300, ANTAGE W-400, and ANTAGE W500 (all manufactured by Kawaguchi Chemical Industry Co., Ltd.), and SEENOX 224M and SEENOX 326M (all manufactured by Shipro Kasei Kaisha, Ltd.), YOSHINOX BHT, YOSHINOX BB, TOMINOX TT, and TOMINOX 917 (all manufactured by Yoshitomi Pharmaceutical Co., Ltd.), and TTHP (manufactured by Toray Industries Inc.).

Specific examples of the phosphorus-based antioxidant include trisnonylphenyl phosphite, tris(2,4-di-t-butylphenyl)phosphite, distearyl pentaerythritol diphosphite, bis(2,4-di-t-butylphenyl)pentaerythritol phosphite, bis(2,6-di-t-butyl-4-methylphenyl)pentaerythritol phosphite, 2,2-methylenebis(4,6-di-t-butylphenyl)octyl phosphite, and tetrakis(2,4-di-t-butylphenyl)-4,4-biphenylene-di-phosphonite. Examples of commercially available phosphorus-based antioxidants include ADEKA STAB 1178 (manufactured by Asahi Denka Co., Ltd.), SUMILIZER TNP (manufactured by Sumitomo Chemical Co., Ltd.), JP-135 (manufactured by Johoku Chemical Co., Ltd.), ADEKA STAB 2112 (manufactured by Asahi Denka Co., Ltd.), JPP-2000 (manufactured by Johoku Chemical Co., Ltd.), Weston 618 (manufactured by GE Co., Ltd.), ADEKA STAB PEP-24G (manufactured by Asahi Denka Co., Ltd.), ADEKA STAB PEP-36 (manufactured by Asahi Denka Co., Ltd.), ADEKA STAB HP-10 (manufactured by Asahi Denka Co., Ltd.), Sandstab P-EPQ (manufactured by Sand Co., Ltd.), and PHOSPHITE 168 (manufactured by BASF Corporation).

Specific examples of the sulfur-based antioxidant include dilauryl-3,3′-thiodipropionate, dimyristyl-3,3′-thiodipropionate, distearyl-3,3′-thiodipropionate, and pentaerythritol tetrakis(3-laurylthiopropionate). Examples of commercially available sulfur-based antioxidants include SUMILIZER TPL (manufactured by Sumitomo Chemical Co., Ltd.), YOSHINOX DLTP (manufactured by Yoshitomi Pharmaceutical Co., Ltd.), ANTIOX L (manufactured by NOF Corporation), SUMILIZER TPM (manufactured by Sumitomo Chemical Co., Ltd.), YOSHINOX DMTP (manufactured by Yoshitomi Pharmaceutical Co., Ltd.), ANTIOX M (manufactured by NOF Corporation), SUMILIZER TPS (manufactured by Sumitomo Chemical Co., Ltd.), YOSHINOX DSTP (manufactured by Yoshitomi Pharmaceutical Co., Ltd.), ANTIOX S (manufactured by NOF Corporation), ADEKA STAB AO-412S (manufactured by Asahi Denka Co., Ltd.), SEENOX 412S (manufactured by Shipro Kasei Kaisha, Ltd.), and SUMILIZER TDP (manufactured by Sumitomo Chemical Co., Ltd.).

In the case where the antioxidant is blended, the content thereof is preferably 0.001 to 5 mass % in the curable composition for imprints. The antioxidant may be contained in one kind or two or more kinds in the curable composition for imprints. In the case where two or more antioxidants are contained, the total amount thereof preferably falls within the above-specified range.

<Other Ingredients>

In addition to the foregoing ingredients, the curable composition for imprints used in the present invention may contain a polymerization inhibitor (for example, 4-hydroxy-2,2,6,6-tetramethylpiperidine-1-oxyl free radical), an ultraviolet absorbing agent, a solvent, and the like, within the scope not departing from the spirit of the present invention. Each of these compounds may be contained in only one kind or two or more kinds thereof. For more details, reference may be made to the description of paragraphs “0061” to “0064” of JP2014-170949A, the contents of which are incorporated by reference herein in its entirety.

Also, in the present invention, it may be possible to adopt an embodiment which is substantially free of a non-polymerizable polymer (a non-polymerizable polymer having preferably a weight-average molecular weight of more than 1,000, more preferably a weight-average molecular weight of more than 2,000, and still more preferably a weight-average molecular weight of 10,000 or more). The phrase “substantially free of a non-polymerizable polymer” means that the content of the non-polymerizable compound is, for example, preferably 0.01 mass % or less and more preferably 0.005 mass % or less. It is still more preferred that the non-polymerizable polymer is not contained.

<Characteristics of Curable Composition for Imprints>

The curable composition for imprints according to the present invention has a viscosity at 25° C. of preferably 12 mPa·s or less, more preferably 11 mPa·s or less, still more preferably 10 mPa·s or less, even more preferably 9 mPa·s or less, and even still more preferably 8 mPa·s or less. The lower limit value of the viscosity is not particularly specified, but it may be set to, for example, 5 mPa·s or more. By setting the viscosity to be within such a range, the curable composition for imprints according to the present invention easily enters the mold, and the mold filling time can be shortened. Further, it is also possible to improve the pattern formability and the throughput.

The Ohnishi parameter of the curable composition for imprints according to the present invention is preferably 4.0 or less, more preferably 3.9 or less, still more preferably 3.8 or less, even still more preferably 3.6 or less, and particularly preferably 3.5 or less. The lower limit value of the Ohnishi parameter is not particularly specified, but it may be set to, for example, 2.8 or more. By setting the Ohnishi parameter to 4.0 or less, it is possible to more effectively suppress, in terms of etching processing characteristics, in particular, pattern disconnection after etching.

The curable composition for imprints according to the present invention may be filtered before use. For filtration, for example, a polytetrafluoroethylene (PTFE) filter can be used. The pore size is preferably 0.003 μm to 5.0 μm. For the details of filtration, reference may be made to the description of paragraph “0070” of JP2014-170949A, the contents of which are incorporated by reference herein in its entirety.

The curable composition for imprints according to the present invention is used as a photocured product. More specifically, it is used by forming a pattern by a photoimprint method. As described above, the cured product of the present invention satisfies a predetermined Tg and a predetermined modulus of elasticity.

<Pattern Forming Method>

The pattern forming method of the present invention involves applying the curable composition for imprints according to the present invention on a substrate or a mold and irradiating the curable composition for imprints with light, in a state where the composition is sandwiched between the mold and the substrate.

In the pattern forming method of the present invention, a pattern is applied on a substrate or a mold. The application method is not particularly specified, and reference may be made to the description of paragraph “0102” of JP2010-109092A (whose corresponding US application is US2011/199592A), the contents of which are incorporated by reference herein in its entirety. In the present invention, a spin coating method or an inkjet method is preferable.

The substrate is not particularly specified, and reference may be made to the description of paragraph “0103” of JP2010-109092A (whose corresponding US application is US2011/199592A), the contents of which are incorporated by reference herein in its entirety. Further examples of the substrate include a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Examples of specific materials of the glass substrate include aluminosilicate glass, aluminoborosilicate glass, and barium borosilicate glass.

In the present invention, a silicon substrate is preferable.

The mold is not particularly specified, reference may be made to the description of paragraphs “0105” to “0109” of JP2010-109092A (whose corresponding US application is US2011/199592A), the contents of which are incorporated by reference herein in its entirety. In the present invention, a quartz mold is preferable. The mold used in the present invention is preferably a mold having a pattern with a size of 50 nm or less, furthermore 30 nm or less.

Subsequently, the curable composition for imprints is irradiated with light in a state of the composition being sandwiched between the mold and the substrate. The step of press-contacting with the substrate or the mold can be preferably carried out under a rare gas atmosphere, a reduced pressure atmosphere, or a reduced pressure rare gas atmosphere. Here, the reduced pressure atmosphere refers to a state in a space fulfilled at a pressure lower than the atmospheric pressure (101,325 Pa), and it is preferably 1,000 Pa or less, more preferably 100 Pa or less, and still more preferably 1 Pa or less. In the case where a rare gas is used, helium is preferable. The exposure dose is preferably in the range of 5 mJ/cm² to 1,000 mJ/cm².

Here, the curable composition for imprints according to the present invention is preferably cured by further heating after irradiation with light. Further, an underlayer film composition may be provided between the substrate and the curable composition layer for imprints.

In addition to the foregoing, the details of the pattern forming method may be referred to the description of paragraphs “0103” to “0115” of JP2010-109092A (whose corresponding US application is US2011/199592A), the contents of which are incorporated by reference herein in its entirety.

According to the pattern forming method of the present invention, it is possible to form a fine pattern with low cost and high accuracy by a photoimprint method (more preferably a photo-nanoimprint method). For this reason, a fine pattern which has been formed by using a conventional photolithography technique can be formed with higher accuracy and at a lower cost. For example, the pattern obtained by the pattern forming method of the present invention can be applied as a permanent film such as an overcoat layer or an insulating film used for a liquid crystal display (LCD) or the like, or an etching resist for a semiconductor integrated circuit, a recording material, a flat panel display, or the like. Particularly, the pattern obtained by the pattern forming method of the present invention is excellent also in etching resistance, and can also preferably be used as an etching resist for dry etching using fluorocarbon or the like.

In a permanent film (resist for a structural member) used in a liquid crystal display (LCD) or the like and a resist used for processing a substrate of an electronic material, in order not to hinder the operation of the product, it is desirable to avoid incorporation of ionic impurities of metals or organic substances into the resist as much as possible. Therefore, the concentration of ionic impurities of metals or organic substances in the curable composition for imprints used in the present invention is preferably 1 parts per million (ppm) by mass or less, more preferably 100 parts per billion (ppb) by mass or less, still more preferably 10 ppb by mass or less, and particularly preferably 100 ppt by mass or less.

The method for removing ionic impurities of metals or organic substances from the curable composition for imprints may be, for example, filtration using a filter. As for the filter pore size, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferred. The filter may be pre-cleaned with an organic solvent. In the step of filtration using a filter, plural kinds of filters may be connected in series or in parallel, and used. In the case of using plural kinds of filters, a combination of filters having different pore sizes and/or materials may be used. In addition, various materials may be filtered plural times, and a step of filtering plural times may be a circulatory filtration step.

Moreover, examples of the method for reducing impurities such as metals contained in the various materials include a method of selecting raw materials having a small content of metals as raw materials constituting various materials, a method of subjecting raw materials constituting various materials to filtration using a filter, and a method of carrying out distillation under the conditions where contamination is suppressed as much as possible by lining the inside of the device with Teflon (registered trademark). The preferred conditions for the filtration using a filter, which is carried out for raw materials constituting various materials, are the same as described above.

In addition to filtration using a filter, removal of impurities by an adsorbing material may be carried out, or a combination of filtration using a filter and filtration using an adsorbing material may be used. As the adsorbing material, known adsorbing materials may be used. For example, inorganic adsorbing materials such as silica gel and zeolite, and organic adsorbing materials such as activated carbon may be used.

<Pattern>

The pattern thus formed by the pattern forming method according to the present invention as described in the above can be used as a permanent film used for an LCD or the like, or as an etching resist for semiconductor processing. Further, by using the pattern according to the present invention to form a grid pattern on a glass substrate of an LCD, it is possible to produce a polarizing plate exhibiting little reflection and absorption and having a large screen size (for example, 55 inches, 60 inches or more) at a low cost. For example, the polarizing plate described in JP2015-132825A or WO2011/132649A can be produced. It should be noted that 1 inch is 25.4 mm.

Meanwhile, the permanent film may be bottled in a container such as a gallon bottle or a coated bottle after production thereof, and may be transported or stored. In this case, the inside of the container may be purged with inert nitrogen, argon, or the like for preventing the permanent film from being degraded. In the case of transportation and storage, the transportation and storage may be carried out at room temperature, but the temperature may be controlled in the range of from −20° C. to 0° C. in order to prevent more alteration of the permanent film. Of course, it is preferred that the permanent film is shielded from light to such a level on which its reaction does not proceed.

More specifically, the pattern of the present invention can be preferably used for the production of a recording medium such as a magnetic disc, a light-receiving element such as a solid image pickup element, a light emitting element such as an LED or an organic EL, an optical device such as an LCD, an optical component such as a diffraction grating, a relief hologram, an optical waveguide, an optical filter, or a microlens array, a thin film transistor, an organic transistor, a color filter, an antireflection film, a polarizing plate, a polarizing element, an optical film, a member for flat panel displays such as a pillar material, a nanobio device, an immunoassay chip, a deoxyribonucleic acid (DNA) separation chip, a microreactor, a photonic liquid crystal, a guide pattern for fine pattern formation (directed self-assembly: DSA) using self-organization of a block copolymer, or the like.

The pattern formed by the pattern forming method of the present invention is also useful as an etching resist (lithography mask). In the case of using a pattern as an etching resist, first, a silicon substrate (silicon wafer or the like) on which a thin film of SiO₂ or the like, for example, is formed, or the like is used as a substrate, and a fine pattern of, for example, nano or micro order is formed on the substrate by the pattern forming method of the present invention. In the present invention, it is particularly advantageous in that a fine pattern of nano order can be formed and furthermore a pattern having a size of 50 nm or less, particularly 30 nm or less can also be formed. The lower limit value of the pattern formed by the pattern forming method of the present invention is not particularly specified, but it may be set to, for example, 1 nm or more.

Thereafter, a desired pattern can be formed on the substrate by etching with hydrogen fluoride or the like in the case of wet etching or with an etching gas such as CF₄ in the case of dry etching. The pattern has good etching resistance, particularly against dry etching. That is, the pattern obtained by the production method of the present invention is preferably used as a lithography mask. Further, in the present invention, a lithography method for carrying out etching using the pattern obtained by the production method of the present invention as a mask is also disclosed.

### Examples

Hereinafter, the present invention will be described in more detail with reference to Examples. Materials, amounts to be used, ratios, details of processes, and procedures of processes described in the following Examples may be modified suitably, without departing from the spirit of the present invention. Therefore, the scope of the present invention is not limited to the following specific examples.

<Preparation of Curable Composition for Imprints>

A polymerizable compound, a photopolymerization initiator, and a mold release agent shown in Tables 2 and 3 given below were mixed in the mass ratio shown in Tables 5 to 9. Further, 4-hydroxy-2,2,6,6-tetramethylpiperidine-1-oxyl free radicals (manufactured by Tokyo Chemical Industry Co., Ltd.) as a polymerization inhibitor were added to 200 ppm by mass (0.02 mass %) relative to the polymerizable compound. This was filtered through a polytetrafluoroethylene (PTFE) filter having a pore size of 0.1 μm to prepare a curable composition for imprints.

<Viscosity>

The viscosity of the curable composition for imprints (before curing) and the polyfunctional polymerizable compound was measured at 25±0.2° C. using an RE-80L type rotational viscometer manufactured by Toki Sangyo Co., Ltd.

The rotation speed at the time of measurement was set as shown in Table 1 given below according to viscosity.

TABLE 1

| Viscosity | Optimum rotation speed |
|---|---|
| 0.001 to 6.076 mPa · s | 100 rpm |
| 6.077 to 12.15 mPa · s | 50 rpm |
| 12.16 to 30.38 mPa · s | 20 rpm |
| 30.39 to 60.76 mPa · s | 10 rpm |
| 60.77 to 121.5 mPa · s | 5 rpm |
| 121.6 to 303.8 mPa · s | 2 rpm |
| 303.9 to 607.6 mPa · s | 1 rpm |
| 607.7 to 1,215 mPa · s | 0.5 rpm |
| 1,216 to 2,025 mPa · s | 0.3 rpm |

<Glass Transition Temperature Tg>

In a state of a curable composition for imprints being sandwiched between quartz glass substrates, the composition was cured under irradiation of ultraviolet light (center wavelength: 365 nm; a wavelength of 300 nm or less is cut by a filter) using a high pressure mercury lamp (illuminance: 10 mW/cm²) at 1,000 mJ/cm² (measured value at a wavelength of 310 nm) to prepare a cured product (cured film) having a film thickness of 150 urn. A striped sample with a width of 5 mm was cut out from the prepared cured product and measured with a dynamic viscoelasticity measuring device DMS-6100 (manufactured by Seiko Instruments Inc.). The measurement was carried out in tensile sinusoidal mode at a distance between chucks of 20 mm, a measurement temperature range of from 20° C. to 220° C. (temperature increase rate of 5° C./min), and a measurement frequency of 1 Hz. The temperature at which the loss coefficient (tan D value) takes a maximum value is defined as the glass transition temperature and the average value of measurements at N=3 is described. In the case where there are two or more glass transition temperatures, the temperature at which the peak surface area of tan D for calculating the glass transition temperature is larger was adopted. The unit is indicated in terms of ° C.

<Modulus of Elasticity of Cured Film>

In a state of a curable composition for imprints being sandwiched between a silicon substrate and a slide glass, the composition was irradiated with ultraviolet light (365 nm; a wavelength of 300 nm or less is cut by a filter) using a high pressure mercury lamp (illuminance: 10 mW/cm²) at 600 mJ/cm² (measured value at a wavelength of 310 nm) to obtain a cured film having a film thickness of 20 μm on the silicon substrate.

The modulus of elasticity of the obtained cured film was measured with a microhardness tester (HM2000 XYp, manufactured by Fischer Instruments K.K.). The measurement was carried out using an indenter in a triangular pyramid form (an angle of 115° between faces) and under the conditions of a test force of 10 mN, a load speed of 0.142 mN/sec, and a holding time of 5 seconds, with a temperature of 25° C. and a humidity of 50% at the time of measurement.

The measurement data was analyzed with analysis software (WIN-HCU, manufactured by Fischer Instruments K.K.) to calculate the modulus of elasticity. The unit is indicated in terms of GPa.

<Filling Time>

A quartz mold having a concave pillar structure with a circle with an opening radius of 1 μm and a depth of 2 μm was used as the quartz mold. The curable composition for imprints was applied onto a silicon wafer by an inkjet method using an inkjet printer DMP-2831 manufactured by FUJIFILM Dimatix Corporation as an inkjet apparatus, and then sandwiched between the above molds under a helium atmosphere.

The state of filling the concave portion of the quartz mold with the curable composition for imprints was observed with a CCD camera, and the time required for completion of filling was measured.

A: shorter than 3 seconds

B: 3 seconds or longer and shorter than 5 seconds

C: 5 seconds or longer and shorter than 10 seconds

D: 10 seconds or longer

<Releasing Force>

A quartz mold having a line/space with a line width of 30 nm and a depth of 60 nm was used as the quartz mold. The curable composition for imprints was applied onto a silicon wafer by an inkjet method using an inkjet printer DMP-2831 manufactured by FUJIFILM Dimatix Corporation as an inkjet apparatus, and then sandwiched between the above molds under a helium atmosphere. Using a high pressure mercury lamp from the quartz mold side, exposure was carried out under the condition of 100 mJ/cm², and then the quartz mold was released to obtain a pattern (hereinafter, referred to as a sample). The thickness of the residual film of the sample was 10 nm. In addition, the force (releasing force F) required for releasing in this case was measured.

A: F≦12N

B: 12N<F≦15N

C: 15N<F≦18N

D: 18N<F≦20N

E: F>20N

<Defect>

The sample prepared by the foregoing evaluation of the releasing force was observed with a scanning electron microscope (SEM) at a magnification of 10,000 times.

A: A good pattern was obtained over the entire surface.

B: Pattern chipping was observed in a partial region.

C: Pattern chipping was observed in a wide range.

D: Pattern collapse was observed over the entire surface.

<ΔLWR>

The sample prepared by the foregoing evaluation of the releasing force was subjected to reactive ion etching using an etching apparatus.

A mixed gas of CHF₃/CF₄/Ar was selected as an etching gas, and the sample was cooled to 20° C. during etching. The etching rate of the sample was about 50 nm/min.

Line width roughness (LWR) was measured from the image obtained by SEM observation (magnification: 100,000 times) of the upper surface (side on which pattern is formed) of the sample before and after etching and the difference of LWR before and after etching (ΔLWR) was calculated. The unit is nm.

ΔLWR=(LWR after etching)−(LWR before etching)

A: 0<ΔLWR≦1.0

B: 1.0<ΔLWR≦2.5

C: 2.5<ΔLWR≦3.0

D: 3.0<ΔLWR≦3.5

E: ΔLWR>3.5

<Disconnection after Etching>

The state of disconnection of the pattern was confirmed from the SEM image of the sample after etching obtained as above.

A: Thinning and disconnection of the line were not observed across the front.

B: Thinning of the line was observed in a partial region, but disconnection of the line was not observed.

C: Disconnection of the line was observed in a partial region.

D: Disconnection of the line was observed over the entire surface

TABLE 2

| | | | | Boiling | |
|---|---|---|---|---|---|
| | | | | point | |
| | | Manufacturer and trade | | (° C.) | Viscosity |
| | | name or synthesis | Ohnishi | (Value at | at 25° C. |
| Symbol | Structural formula | method | parameter | 667 Pa) | (mPa • S) |
| A-1 | 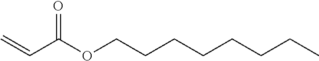 | Osaka Organic Chemical Industry, Ltd. Trade name: NOAA | 3.7 | 91 | 1.9 |
| A-2 | 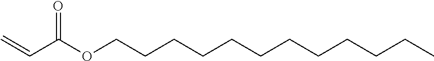 [SMILES: C=CC(=O)OCCCCCCCCCCCC] | Kyoeisha Chemical Co., Ltd. Trade name: LIGHT ACRYLATE L-A | 3.5 | 137 | 3.9 |
| A-3 | 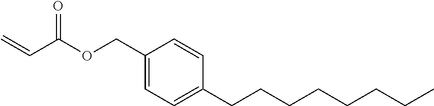 [SMILES: C=CC(=O)OCc1ccc(CCCCCCCC)cc1] | Synthesized from 4-octyl benzyl alcohol and acryloyl chloride | 2.9 | >160 | 5.6 |
| A-4 | 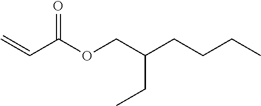 | Nippon Shokubai Co., Ltd. Trade name: 2ethylhexyl acrylate (AEH) | 3.7 | 87 | 1.6 |
| A-5 | 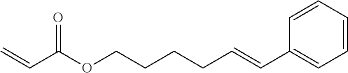 [SMILES: C=CC(=O)OCCCC/C=C/c1ccccc1] | | 2.7 | >160 | 10 |
| A-6 | 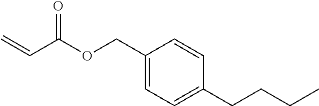 [SMILES: C=CC(=O)OCc1ccc(CCCC)cc1] | Synthesized from 4-butylbenzyl alcohol and acryloyl chloride | 2.8 | 160 | 3.9 |
| A-7 | 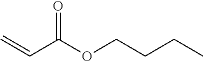 | Mitsubishi Chemical Corporation Trade name: butyl acrylate (BA) | 4.2 | <50 | 0.9 |
| A-8 | 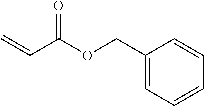 | Osaka Organic Chemical Industry, Ltd. Trade name: VISCOAT #160 | 2.8 | 84 | 2.3 |
| A-9 | 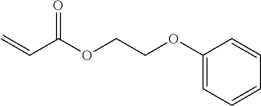 | Osaka Organic Chemical Industry, Ltd. Trade name: VISCOAT #192 | 3.3 | 130 | 8.3 |
| A-10 | 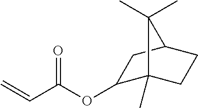 | Osaka Organic Chemical Industry, Ltd. Trade name: IBXA | 3.2 | 96 | 7.1 |
| A-11 | 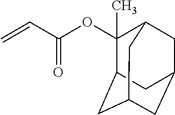 [SMILES: C=CC(=O)OC1(C)C2CC3CC(C2)CC1C3] | Osaka Organic Chemical Industry, Ltd. Trade name: MADA | 3.0 | 149 | 31.7 |
| A-12 | 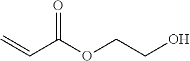 | Kyoeisha Chemical Co., Ltd. Trade name: LIGHT ESTER HOA(N) | 8.0 | 77 | 5.3 |
| A-13 | 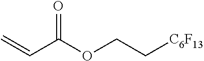 | Unimatec Co., Ltd. Trade name: FAAC-6 | 2.2 | 69 | 4.1 |

TABLE 3

| | | Manufacturer and trade | | Viscosity at |
|---|---|---|---|---|
| | | name or synthesis | Ohnishi | 25° C. |
| Symbol | Structural formula | method | parameter | (mPa • s) |
| B-1 | 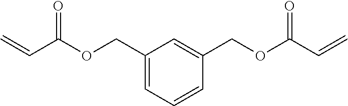 [SMILES: C=CC(=O)OCc1cccc(COC(=O)C=C)c1] | Synthesized from α,α′-dichloro-m-xylene and acrylic acid | 3.2 | 9.7 |
| B-2 | 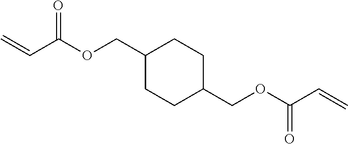 [SMILES: C=CC(=O)OCC1CCC(COC(=O)C=C)CC1] | Synthesized from 1,4-cyclohexane dimethanol and acryloyl chloride | 3.8 | 20 |
| B-3 | 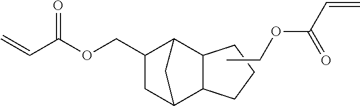 | Shin-Nakamura Chemical Co., Ltd. Trade name: A-DCP | 3.8 | 120 |
| B-4 | 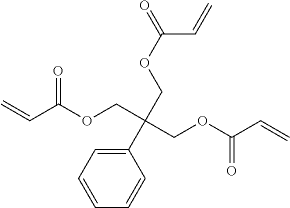 [SMILES: C=CC(=O)OCC(COC(=O)C=C)(COC(=O)C=C)c1ccccc1] | | 3.5 | ≧2,000 |
| B-5 | 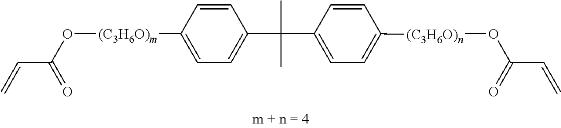 | Kyoeisha Chemical Co., Ltd. Trade name: LIGHT ACRYLATE BP-4PA | 3.8 | ≧2,000 |
| B-6 | 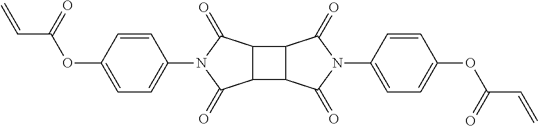 [SMILES: C=CC(=O)Oc1ccc(N2C(=O)C3C(C2=O)C2C(=O)N(c4ccc(OC(=O)C=C)cc4)C(=O)C32)cc1] | | 3.0 | ≧2,000 |
| B-7 | 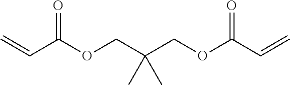 | Shin-Nakamura Chemical Co., Ltd. Trade name: A-NPG | 4.4 | 4.5 |
| B-8 | 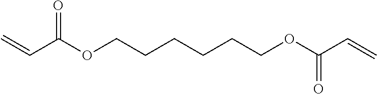 [SMILES: C=CC(=O)OCCCCCCOC(=O)C=C] | Shin-Nakamura Chemical Co., Ltd. Trade name: A-HD-N | 4.3 | 5.4 |
| B-9 | 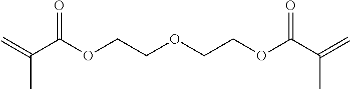 [SMILES: C=C(C)C(=O)OCCOCCOC(=O)C(=C)C] | Kyoeisha Chemical Co., Ltd. Trade name: LIGHT ESTER 2EG | 5.0 | 5.2 |
| B-10 | 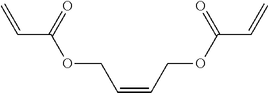 | Synthesized from cis-2-butene-1,4-diol and acryloyl chloride | 4.3 | 3.2 |
| B-11 | 3-methyl-1,5-pentanediol diacrylate 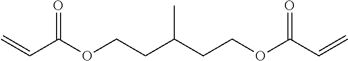 [SMILES: C=CC(=O)OCCC(C)CCOC(=O)C=C] | SR341 manufactured by Sartomer | 4.3 | 4.6 |

TABLE 4

| Symbol | Structural formula | Manufacturer and trade name or synthesis method |
|---|---|---|
| C-1 | 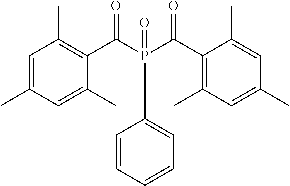 | BASF Trade name: IRGACURE 819 |
| C-2 | 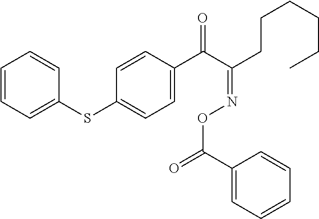 [SMILES: CCCCCC/C(=N/OC(=O)c1ccccc1)C(=O)c1ccc(Sc2ccccc2)cc1] | BASF Trade name: IRGACURE OXE-01 |
| C-3 | 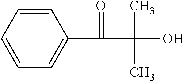 | BASF Trade name: IRGACURE 1173 |
| C-4 | 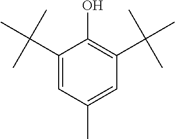 [SMILES: Cc1cc(C(C)(C)C)c(O)c(C(C)(C)C)c1] | BHT manufactured by Tokyo Chemical Industry Co., Ltd. |
| C-5 | 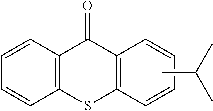 | ESACURE ITX manufactured by Lamberti |
| D-1 | Fluorine-containing surfactant having | Neos Company Limited |
| | PEO structure | Trade name: FTERGENT 212M |
| D-2 | Fluorine-containing surfactant having | E.I. du Pont de Nemours and Company |
| | PEO structure | Trade name: Capstone FS-3100 |
| D-3 | 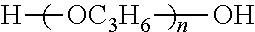 Mn ~700 | ADEKA Corporation Trade name: ADEKA POLYETHER P-700 |
| D-4 | 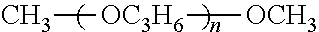 Mn ~728 | Synthesized by methylating both terminals of ADEKA POEYETHER P-700 |
| D-5 | 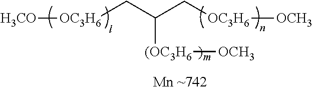 | Synthesized by methylating terminal of ADEKA POLYETHER G-700 |
| D-6 | 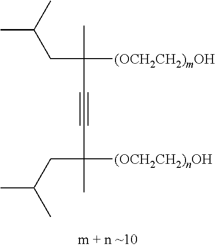 | Nissin Chemical Industry Co., Ltd. Trade name: OLFINE E 1010 |

TABLE 5

| | | Example 1 | Example 2 | Example 3 | Example 4 | Example 5 | Example 6 | Example 7 | Example 8 | Example 9 |
|---|---|---|---|---|---|---|---|---|---|---|
| A-1 | | 20 | | | | | | | | |
| A-2 | | | 25 | | | | | 20 | 25 | |
| A-3 | | | | 20 | | | | | | 10 |
| A-4 | | | | | 20 | | | | | |
| A-5 | | | | | | 20 | | | | |
| A-6 | | | | | | | 29 | | | |
| A-7 | | | | | | | | | | |
| A-8 | | | | | | | | | | |
| A-9 | | | | | | | | | | |
| A-10 | | | | | | | | | | |
| A-11 | | | | | | | | | | |
| A-12 | | | | | | | | | | |
| A-13 | | | | | | | | | 1 | |
| B-1 | | 80 | 75 | | 80 | 80 | | 60 | 60 | |
| B-2 | | | | 80 | | | 61 | | | 65 |
| B-3 | | | | | | | | | | |
| B-4 | | | | | | | | | | |
| B-5 | | | | | | | | | | |
| B-6 | | | | | | | | | | |
| B-7 | | | | | | | | | 14 | |
| B-8 | | | | | | | 10 | 20 | | 25 |
| B-9 | | | | | | | | | | |
| C-1 | | 2 | 2 | | 2 | 2 | 2 | 2 | 2 | 2 |
| C-2 | | | | 2 | | | | | | |
| C-3 | | | | | | | 2 | | | |
| D-1 | | | | | | | 3 | | | |
| D-2 | | | | | | | | 3 | | |
| D-3 | | 3 | | | | | | | | |
| D-4 | | | 3 | | 3 | 3 | | | | |
| D-5 | | | | | | | | | 3 | |
| D-6 | | | | 3 | | | | | | 3 |
| Characteristics | Viscosity (composition) | 8 | 8 | 8 | 7 | 8 | 8 | 7 | 7 | 8 |
| | Tg (cured film) | 110 | 110 | 95 | 110 | 110 | 90 | 100 | 105 | 120 |
| | Modulus of elasticity | 2.7 | 2.0 | 2.3 | 2.7 | 3.0 | 3.0 | 1.9 | 2.1 | 2.1 |
| | (cured film) | | | | | | | | | |
| | Ohnishi parameter | 3.3 | 3.3 | 3.5 | 3.3 | 3.1 | 3.6 | 3.5 | 3.4 | 3.8 |
| Evaluation | Filling time | A | A | A | A | A | A | A | A | A |
| | Releasing force | A | A | A | B | B | B | A | A | A |
| | Defect | A | A | A | A | A | A | A | A | A |
| | ΔLWR | A | A | A | A | A | B | A | A | A |
| | Disconnection after | A | A | A | A | A | A | A | A | B |
| | etching | | | | | | | | | |

TABLE 6

| | | Example 10 | Example 11 | Example 12 | Example 13 | Example 14 | Example 15 | Example 16 |
|---|---|---|---|---|---|---|---|---|
| A-1 | | | 9 | 29 | | | | |
| A-2 | | 19 | | | | | | 25 |
| A-3 | | 10 | | | | 20 | | |
| A-4 | | | | | | | 20 | |
| A-5 | | | | | | | | |
| A-6 | | | | | 20 | | | |
| A-7 | | | | | | | | |
| A-8 | | | | | | | | |
| A-9 | | | | | | | | |
| A-10 | | | | | | | | |
| A-11 | | | | | | | | |
| A-12 | | | | | | | | |
| A-13 | | | | | | | | |
| B-1 | | 50 | | | 80 | 50 | | 70 |
| B-2 | | 11 | 91 | | | | 50 | |
| B-3 | | | | 71 | | | | |
| B-4 | | | | | | | | 5 |
| B-5 | | | | | | | | |
| B-6 | | | | | | | | |
| B-7 | | | | | | | | |
| B-8 | | 10 | | | | 30 | 30 | |
| B-9 | | | | | | | | |
| C-1 | | 2 | 2 | 2 | 2 | 2 | | 2 |
| C-2 | | | | | | | 2 | |
| C-3 | | | | | | | | |
| D-1 | | | | | | | | |
| D-2 | | | | | | | | |
| D-3 | | 3 | 3 | | 3 | | | |
| D-4 | | | | | | | | |
| D-5 | | | | | | | | |
| D-6 | | | | 3 | | 3 | | |
| Characteristics | Viscosity (composition) | 8 | 9 | 10 | 9 | 7 | 6 | 11 |
| | Tg (cured film) | 90 | 135 | 90 | 115 | 95 | 93 | 135 |
| | Modulus of elasticity (cured film) | 1.5 | 2.7 | 1.8 | 2.7 | 2.1 | 2.7 | 2.7 |
| | Ohnishi parameter | 3.4 | 3.3 | 3.8 | 3.1 | 3.5 | 3.9 | 3.3 |
| Evaluation | Filling time | A | A | B | B | A | A | B |
| | Releasing force | A | B | A | B | A | B | B |
| | Defect | A | B | B | A | A | A | A |
| | ΔLWR | B | A | B | A | A | A | A |
| | Disconnection after etching | A | A | B | A | A | B | A |

TABLE 7

| | | Comparative | Comparative | Comparative | Comparative | Comparative | Comparative | Comparative | Comparative |
|---|---|---|---|---|---|---|---|---|---|
| | | Example 1 | Example 2 | Example 3 | Example 4 | Example 5 | Example 6 | Example 7 | Example 8 |
| A-1 | | | | | | 20 | | | |
| A-2 | | 40 | | | | | | | |
| A-3 | | | | | | | | | |
| A-4 | | | | | | | | | |
| A-5 | | | 40 | | | | | | |
| A-6 | | | | | | | | | |
| A-7 | | | | | | | | | 30 |
| A-8 | | | | 50 | | | 30 | | |
| A-9 | | | | | | | | 30 | |
| A-10 | | | | | 40 | | | | |
| A-11 | | | | | | | | | |
| A-12 | | | | | | | | | |
| A-13 | | | | | | | | | |
| B-1 | | 60 | 60 | 50 | | 30 | 70 | | 70 |
| B-2 | | | | | 60 | | | 70 | |
| B-3 | | | | | | | | | |
| B-4 | | | | | | | | | |
| B-5 | | | | | | | | | |
| B-6 | | | | | | | | | |
| B-7 | | | | | | | | | |
| B-8 | | | | | | 50 | | | |
| B-9 | | | | | | | | | |
| C-1 | | 2 | 2 | 2 | | 2 | 2 | 2 | |
| C-2 | | | | | 2 | | | | 2 |
| C-3 | | | | | | | | | |
| D-1 | | | | | | | | | |
| D-2 | | | | | | | | | |
| D-3 | | 3 | | | 3 | | 3 | | 3 |
| D-4 | | | 3 | 3 | | | | 3 | |
| D-5 | | | | | | | | | |
| D-6 | | | | | | 3 | | | |
| Characteristics | Viscosity | 7 | 8 | 6 | 6 | 7 | 7 | 11 | 6 |
| | (composition) | | | | | | | | |
| | Tg (cured film) | 80 | 85 | 65 | 75 | 75 | 105 | 90 | 105 |
| | Modulus of | 1.0 | 1.2 | 3.3 | 3.1 | 2.2 | 3.7 | 3.2 | 3.1 |
| | elasticity | | | | | | | | |
| | (cured film) | | | | | | | | |
| | Ohnishi parameter | 3.3 | 3.0 | 3.0 | 3.6 | 3.9 | 3.1 | 3.7 | 3.5 |
| Evaluation | Filling time | A | A | A | A | A | A | C | A |
| | Releasing force | A | A | C | C | A | D | D | C |
| | Defect | A | A | A | A | A | A | B | A |
| | ΔLWR | C | C | E | D | D | A | A | A |
| | Disconnection | A | A | A | A | C | A | A | A |
| | after etching | | | | | | | | |

TABLE 8

| | | Comparative | Comparative | Comparative | Comparative | Comparative | Comparative | Comparative |
|---|---|---|---|---|---|---|---|---|
| | | Example 9 | Example 10 | Example 11 | Example 12 | Example 13 | Example 14 | Example 15 |
| A-1 | | | | | | | | |
| A-2 | | 10 | 20 | | | 40 | 44 | |
| A-3 | | | | | | | | |
| A-4 | | | | | | | | |
| A-5 | | | | | | | | |
| A-6 | | | | 40 | | | | |
| A-7 | | | | | | | | |
| A-8 | | | | | | | | |
| A-9 | | | | | | | | |
| A-10 | | | | | | | | |
| A-11 | | | | | | | | 35 |
| A-12 | | | | | | 40 | | |
| A-13 | | | | | | | | 20 |
| B-1 | | | | 60 | 65 | | | |
| B-2 | | | | | | | | |
| B-3 | | | | | | | | |
| B-4 | | | | | | | | |
| B-5 | | | | | | 20 | | 35 |
| B-6 | | | | | | | 23 | |
| B-7 | | 90 | | | | | | |
| B-8 | | | 80 | | 35 | | 33 | |
| B-9 | | | | | | | | 10 |
| C-1 | | 2 | 2 | | 2 | 2 | 5 | 4 |
| C-2 | | | | 2 | | | | |
| C-3 | | | | | | | | |
| D-1 | | | | | | | | |
| D-2 | | | | | | | | |
| D-3 | | 3 | 3 | | | | | |
| D-4 | | | | 3 | 3 | | | |
| D-5 | | | | | | | | |
| D-6 | | | | | | | | |
| Characteristics | Viscosity (composition) | 5 | 5 | 7 | 8 | 30 or more | 30 or more | 30 or more |
| | Tg (cured film) | 75 | 60 | 80 | 140 | 30 | 70 | 50 |
| | Modulus of elasticity (cured film) | 2.3 | 1.1 | 2.5 | 3.1 | 1.1 | 1.0 | 1.0 |
| | Ohnishi parameter | 4.3 | 4.1 | 3.0 | 3.6 | 5.4 | 3.6 | 3.6 |
| Evaluation | Filling time | A | A | A | A | D | D | D |
| | Releasing force | B | A | A | D | B | C | E |
| | Defect | A | A | D | A | D | D | D |
| | ΔLWR | D | E | — | A | — | — | — |
| | Disconnection after etching | D | D | — | A | — | — | — |

TABLE 9

| | | Exam- | Exam- | Exam- |
|---|---|---|---|---|
| | | ple 17 | ple 18 | ple 19 |
| A-2 | | 25 | 20 | 15 |
| B-1 | | 60 | 60 | 60 |
| B-10 | | 15 | 20 | 25 |
| C-1 | | 2 | 2 | 2 |
| D-5 | | 3 | 3 | 3 |
| Characteristics | Viscosity (composition) | 7.3 | 7.2 | 7.2 |
| | Tg (cured film) | 102 | 112 | 122 |
| | Modulus of elasticity | 2.0 | 2.1 | 2.2 |
| | (cured film) | | | |
| | Ohnishi parameter | 3.4 | 3.5 | 3.5 |
| Evaluation | Filling time | A | A | A |
| | Releasing force | A | A | A |
| | Defect | A | A | A |
| | ΔLWR | A | A | A |
| | Disconnection after | A | A | A |
| | etching | | | |

TABLE 10

| | | Exam- | Exam- | Exam- | Exam- |
|---|---|---|---|---|---|
| | | ple 20 | ple 21 | ple 22 | ple 23 |
| A-1 | | | | | |
| A-2 | | 20 | 25 | | 20 |
| A-3 | | | | 20 | |
| A-4 | | | | | |
| A-5 | | | | | |
| A-6 | | | | | |
| A-7 | | | | | |
| A-8 | | | | | |
| A-9 | | | | | |
| A-10 | | | | | |
| A-11 | | | | | |
| A-12 | | | | | |
| A-13 | | | | | |
| B-1 | | 60 | 55 | | 60 |
| B-2 | | | | 80 | |
| B-3 | | | | | |
| B-4 | | | | | |
| B-5 | | | | | |
| B-6 | | | | | |
| B-7 | | | | | |
| B-8 | | | | | |
| B-9 | | | | | |
| B-10 | | | | | 20 |
| B-11 | | 20 | 20 | | |
| C-1 | | 2 | 2 | 2 | 2 |
| C-2 | | | | | |
| C-3 | | | 2 | | |
| C-4 | | | | 1 | |
| C-5 | | | | | 1 |
| D-1 | | | | | |
| D-2 | | | | | |
| D-3 | | | | 3 | |
| D-4 | | | | | 3 |
| D-5 | | 3 | 3 | | |
| D-6 | | | | | |
| Charac- | Viscosity (composition) | 8 | 8 | 8 | 7 |
| teristics | Tg (cured film) | 113 | 102 | 119 | 120 |
| | Modulus of elasticity | 1.9 | 1.7 | 2.5 | 2.1 |
| | (cured film) | | | | |
| | Ohnishi parameter | 3.5 | 3.5 | 3.5 | 3.5 |
| Evalua- | Filling time | A | A | A | A |
| tion | Releasing force | A | A | A | A |
| | Defect | A | A | A | A |
| | ΔLWR | A | A | A | A |
| | Disconnection after | A | A | A | A |
| | etching | | | | |

As is clear from the above results, in the case where the curable composition for imprints according to the present invention was used, it has been demonstrated that the releasing force was small, that is, the releasability was improved, the difference in ΔLWR was small, and occurrence of the waviness during etching could be suppressed. Further, it has been demonstrated that the filling time of the curable composition for imprints into the mold could be shortened, pattern defects of the obtained pattern were few, and disconnection of the pattern after etching was small. On the other hand, in the case where the curable composition for imprints of the Comparative Examples was used, at least one of the releasing force or the difference in ΔLWR became larger. Further, it has been demonstrated that the filling time became longer, the number of pattern defects increased, and the pattern disconnection after etching increased in some cases.

What is claimed is:

1. A curable composition for imprints, comprising:
a monofunctional polymerizable compound;
a polyfunctional polymerizable compound containing at least one of an alicyclic structure and an aromatic ring structure and having a viscosity at 25° C. of 150 mPa·s or less; and
a photopolymerization initiator,
wherein the monofunctional polymerizable compound is contained in an amount of more than 5 mass % and less than 30 mass % with respect to the total polymerizable compound in the curable composition for imprints, and
the cured film of the curable composition for imprints has a modulus of elasticity of 3.5 GPa or less and a glass transition temperature of 90° C. or higher,
where the modulus of elasticity is a value for a film having a thickness of 20 μm in terms of a cured film of a curable composition for imprints, as measured by a microhardness tester, the indenter at this time is of a triangular pyramid form with an angle of 115° between faces, and the measurement is carried out under the conditions of a test force of 10 mN, a load speed of 0.142 mN/sec, and a holding time of 5 seconds, with a temperature of 25° C. and a humidity of 50% at the time of measurement.

2. The curable composition for imprints according to claim 1,
wherein the monofunctional polymerizable compound has a linear or branched hydrocarbon chain having 4 or more carbon atoms.

3. The curable composition for imprints according to claim 2,
wherein the hydrocarbon chain is a linear or branched alkyl group.

4. The curable composition for imprints according to claim 3,
wherein the hydrocarbon chain is a linear alkyl group.

5. The curable composition for imprints according to claim 1,
wherein a polymerizable group of the monofunctional polymerizable compound and a polymerizable group of the polyfunctional polymerizable compound containing at least one of an alicyclic structure and an aromatic ring structure are (meth)acryloyloxy groups.

6. The curable composition for imprints according to claim 1,
wherein the polyfunctional polymerizable compound containing at least one of an alicyclic structure and an aromatic ring structure is a difunctional polymerizable compound.

7. The curable composition for imprints according to claim 1,
wherein at least one of the polyfunctional polymerizable compounds containing at least one of an alicyclic structure and an aromatic ring structure is represented by General Formula (1), 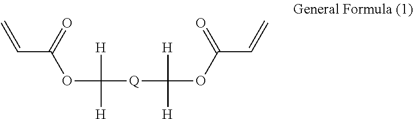
in General Formula (1), Q represents a divalent group having an alicyclic structure or an aromatic ring structure.

8. The curable composition for imprints according to claim 1,
wherein the polyfunctional polymerizable compound containing at least one of an alicyclic structure and an aromatic ring structure has a viscosity at 25° C. of 50 mPa·s or less.

9. The curable composition for imprints according to claim 1,
wherein the monofunctional polymerizable compound is contained in an amount of 10 to 25 mass % with respect to the total polymerizable compound in the curable composition for imprints.

10. The curable composition for imprints according to claim 1,
wherein the polyfunctional polymerizable compound containing at least one of an alicyclic structure and an aromatic ring structure is contained in an amount of 45 to 90 mass % with respect to the total polymerizable compound in the curable composition for imprints.

11. A curable composition for imprints, comprising:
a monofunctional polymerizable compound having a linear or branched alkyl group having 8 or more carbon atoms and having a viscosity at 25° C. of 10 mPa·s or less;
a difunctional polymerizable compound containing at least one of an alicyclic structure and an aromatic ring structure and having a viscosity at 25° C. of 50 mPa·s or less; and
a photopolymerization initiator,
wherein, with respect to the total polymerizable compound in the curable composition for imprints, the monofunctional polymerizable compound is contained in an amount of 10 to 25 mass % and the difunctional polymerizable compound is contained in an amount of 45 to 90 mass %.

12. The curable composition for imprints according to claim 1,
wherein the Ohnishi parameter of the curable composition for imprints is 4.0 or less.

13. The curable composition for imprints according to claim 1,
wherein the curable composition for imprints has a viscosity at 25° C. of 12 mPa·s or less.

14. The curable composition for imprints according to claim 1, further comprising:
a mold release agent.

15. The curable composition for imprints according to claim 1, further comprising:
a polyfunctional polymerizable compound containing no alicyclic structure and aromatic ring structure and having a viscosity at 25° C. of 10 mPa·s or less.

16. The curable composition for imprints according to claim 1,
wherein the modulus of elasticity is 3.1 GPa or less.

17. A cured product obtained by curing the curable composition for imprints according to claim 1.

18. The cured product according to claim 17,
wherein the cured product is located on a silicon substrate.

19. A pattern forming method, comprising:
applying the curable composition for imprints according to claim 1 onto a substrate or a mold; and
subjecting the curable composition for imprints to light irradiation in a state of the curable composition for imprints being sandwiched between the mold and the substrate.

20. The pattern forming method according to claim 19,
wherein the size of the pattern is 30 nm or less.

21. A lithography method,
wherein etching is carried out using a pattern obtained by the method according to claim 19 as a mask.

22. A pattern which is a cured product of the curable composition for imprints according to claim 1 and has a pattern size of 30 nm or less.

23. A lithography mask comprising:
at least one of the patterns according to claim 22.
